(19) United States
(12) Patent Application Publication
(10) Pub. No.: US 2022/0141385 A1
(43) Pub. Date: May 5, 2022

(54) IMAGING APPARATUS AND SWITCH

(71) Applicant: SONY GROUP CORPORATION, TOKYO (JP)

(72) Inventor: TAKASHI ISHIHARA, TOKYO (JP)

(21) Appl. No.: 17/433,486

(22) PCT Filed: Feb. 20, 2020
(86) PCT No.: PCT/JP2020/006939

§ 371 Date: Aug. 24, 2021

(30) Foreign Application Priority Data
Mar. 6, 2019 (JP) 2019-040319

(51) Int. Cl. H04N 5/232; H01H 13/66; H01H 9/16; G03B 17/18

(52) U.S. Cl. CPC H04N 5/23245; G03B 17/18; H01H 9/161; H01H 13/66

(57) ABSTRACT

A configuration is implemented that can adjust a stroke of an operation section of a switch required to cause predetermined processing to be executed. The present disclosure includes an operation section that can move in a predetermined direction from an initial position by a user operation, a position adjustment section that adjusts, in the predetermined direction, an amount of movement of the operation section from the initial position to a detection position, a position detection section that detects a position of the operation section with respect to the detection position, and a control section that controls execution of processing corresponding to the detection position based on a detection result from the position detection section.

### TECHNICAL FIELD

The present disclosure relates to an imaging apparatus and a switch. For example, the present disclosure relates to a release switch provided in an imaging apparatus to capture images.

### BACKGROUND ART

For example, in a case of capturing an image using an imaging apparatus (camera or the like), a user performs an operation of depressing a button (hereinafter referred to as an operation section) of a release switch of the imaging apparatus.

Many existing imaging apparatuses include an autofocus (AF) function and are configured to execute AF processing in a case where the operation section of the release switch is in a half-depressed state and to execute image capturing processing for capturing images in a case where the operation section of the release switch is in a fully-depressed state. Additionally, in some imaging apparatuses, exposure processing is also executed by operating the release switch.

Note that, for example, PTL 1 (JP 2012-227644A) is a known technique disclosing an imaging apparatus including the switch configuration as described above.

The release switch of such an imaging apparatus has a fixed half-depressed position where AF processing is executed and a fixed fully-depressed position where image capturing processing is executed. Thus, it is desirable that the user can adjust the degree of pressing (that is, a stroke corresponding to the amount of movement over which the operation section of the release switch moves from an initial position to arrive at these positions).

### CITATION LIST

### Patent Literature

[PTL 1]

JP 2012-227644A

### SUMMARY

### Technical Problem

An object of the present disclosure is to provide an imaging apparatus and a switch including a configuration such as a release switch of an imaging apparatus which detects that a user has depressed an operation section down to a predetermined position and then which executes certain processing such as autofocus (AF) processing or image capturing processing, a stroke of the operation section down to a position where each step of processing is executed being adjustable.

### Solution to Problem

A first aspect of the present disclosure provides an imaging apparatus including:

an operation section that can move in a predetermined direction from an initial position by a user operation;

a position adjustment section that adjusts, in the predetermined direction, an amount of movement of the operation section from the initial position to a detection position;

a position detection section that detects a position of the operation section with respect to the detection position; and

a control section that controls execution of processing corresponding to the detection position based on a detection result from the position detection section.

Further, a second aspect of the present disclosure provides a switch including:

an operation section that can move in a predetermined direction from an initial position by a user operation;

a position adjustment section that adjusts, in the predetermined direction, an amount of movement of the operation section from the initial position to a detection position; and

a position detection section that detects a position of the operation section with respect to the detection position.

Other objects, features, and advantages of the present disclosure will be clarified by more detailed description based on examples of the present disclosure described below and attached drawings. Note that a system as used herein refers to a logical set configuration of plural apparatuses and is not limited to apparatuses having different configurations and provided in the same housing.

### Advantageous Effect of Invention

The present configuration implements a configuration that can adjust the stroke of the operation section of the release switch or the like.

Note that effect described herein is only illustrative and not restrictive and that additional effects may be produced.

### BRIEF DESCRIPTION OF DRAWINGS

FIG. 1 is a view illustrating an appearance of an imaging apparatus of the present disclosure.

FIG. 2 is a diagram illustrating a configuration example of a release switch of the present disclosure.

FIG. 3 is a block diagram of the imaging apparatus of the present disclosure.

FIG. 4 is a diagram describing a position detection section and a processing control section of the imaging apparatus of the present disclosure.

FIG. 5 is a diagram illustrating a configuration example in which plural detection positions are provided.

FIG. 6 is a diagram illustrating a configuration and processing of a release switch in a first example of the present disclosure.

FIG. 7 is a diagram illustrating a correspondence relation between a position (height) of an S2 photo interrupter and a stroke L2 of the operation section.

FIG. 8 is a diagram illustrating a configuration example in which a position of an S1 photo interrupter can also be moved up and down.

FIG. 9 is a diagram illustrating a configuration and processing of a release switch in a second example of the present disclosure.

FIG. 10 is a diagram illustrating an example in which the S1 photo interrupter also includes S1 light emission sections (1 to m) including plural (m) light emission sections.

FIG. 11 is a diagram illustrating a configuration and processing of a modified example of a release switch in a second example of the present disclosure.

FIG. 12 is a diagram illustrating a configuration example that prevents reception of output light from a light emission section of another photo interrupter.

FIG. 13 is another diagram illustrating a configuration example that prevents reception of the output light from the light emission section of another photo interrupter.

FIG. 14 is still another diagram illustrating a configuration example that prevents reception of the output light from the light emission section of another photo interrupter.

FIG. 15 is a diagram illustrating an example in which a power saving configuration is applied to the release switch in Example 2.

FIG. 16 is a diagram illustrating the power saving configuration example.

FIG. 17 is a diagram illustrating an example in which a vibrator is built in the operation section of the release switch.

FIG. 18 is a diagram illustrating an example of vibration control of the vibrator.

FIG. 19 is a diagram illustrating a configuration and processing of an example of the release switch of the present disclosure.

FIG. 20 is another diagram illustrating the configuration and processing of an example of the release switch of the present disclosure.

FIG. 21 is still another diagram illustrating the configuration and processing of an example of the release switch of the present disclosure.

FIG. 22 is a diagram illustrating an example of an operation section holding mechanism.

FIG. 23 is a diagram illustrating the operation section holding mechanism and an example of an adjustment configuration for an initial position (S0).

FIG. 24 is a diagram illustrating a configuration and processing of a release switch in a fifth example of the present disclosure.

FIG. 25 is a diagram illustrating the configuration of the release switch in the fifth example of the present disclosure.

FIG. 26 is a diagram illustrating an example of adjustment of a stroke by rotation of the release switch.

FIG. 27 is another diagram illustrating the configuration of the release switch in the fifth example of the present disclosure.

FIG. 28 is another diagram illustrating an example of adjustment of the stroke by the rotation of the release switch.

FIG. 29 is still another diagram illustrating an example of adjustment of the stroke by the rotation of the release switch.

FIG. 30 is a view schematically depicting a general configuration of an operating room system.

FIG. 31 is a view depicting an example of display of an operation screen image of a centralized operation panel.

FIG. 32 is a view illustrating an example of a state of surgery to which the operating room system is applied.

FIG. 33 is a block diagram depicting an example of a functional configuration of a camera head and a camera control unit (CCU) depicted in FIG. 32.

### DESCRIPTION OF EMBODIMENTS

Details of an imaging apparatus and a switch in the present disclosure will be described below with reference to the drawings. Note that the following items will be described in the following order.

1. Configuration Example of Imaging Apparatus of Present Disclosure

2. Configuration and Processing of Release Switch in First Example of Present Disclosure

3. Configuration and Processing of Release Switch in Second Example of Present Disclosure

4. Configuration and Processing of Modified Example of Release Switch in Second Example of Present Disclosure

5. Third Example—Power Saving Type Example

6. Fourth Example—Example with Processing Notification Function

7. Operation Section Holding Mechanism and Example of Adjustment Configuration for Initial Position (S0)

8. Configuration and Processing of Release Switch in Fifth Example of Present Disclosure

9. Other Modified Examples

10. Applied Examples

11. Conclusion for Configurations of Present Disclosure

### 1. Configuration Example of Imaging Apparatus of Present Disclosure

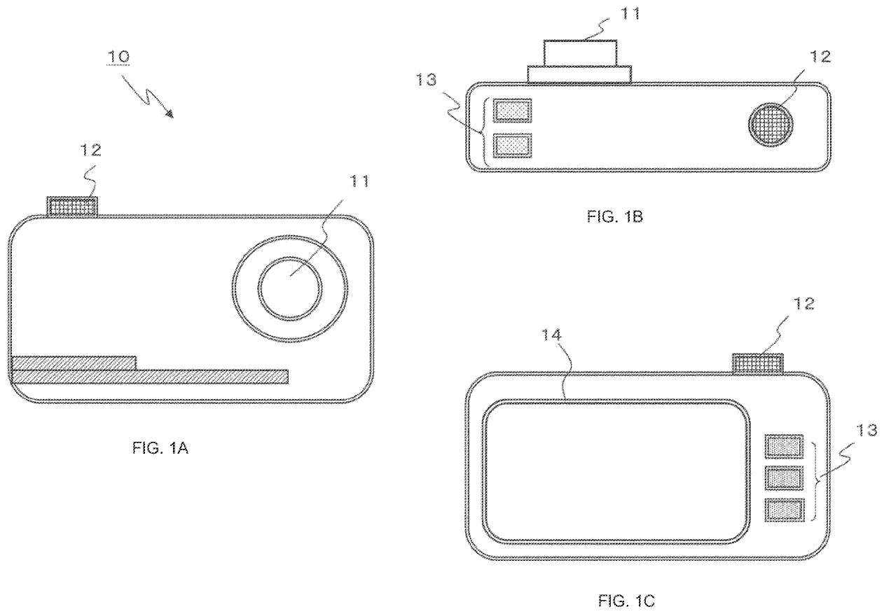

FIG. 1 is a diagram depicting an appearance of an imaging apparatus 10, FIG. 1(a) depicts a front view, FIG. 1(b) is a top view, and FIG. 1(c) is a rear view. Note that, in the figures, when an imaging apparatus 10 is directed to a subject to capture an image, a front surface corresponds to a surface that faces a subject side, a rear surface corresponds to a surface opposite to the front surface, and a top surface corresponds to a surface located on a top side of the front surface and the rear surface. As depicted in FIGS. 1(a) to 1(c), a lens 11 is disposed on a front surface of the imaging apparatus 10, a release switch 12 and a part of a user input section 13 are disposed on a top surface of the imaging apparatus 10, and a part of the user input section 13 and a display section 14 are disposed on a rear surface of the imaging apparatus 10. Note that the release switch 12 depicted in FIG. 1 is a part of the whole structure.

In a case of capturing an image using the imaging apparatus 10, a user performs an operation (depressing operation) of depressing the operation section of the release switch 12 of the imaging apparatus 10 with respect to the top surface of the imaging apparatus 10. At this time, according to depression of the operation section down to a predetermined position, the imaging apparatus 10 executes various types of processing such as autofocus (AF) processing and image capturing processing.

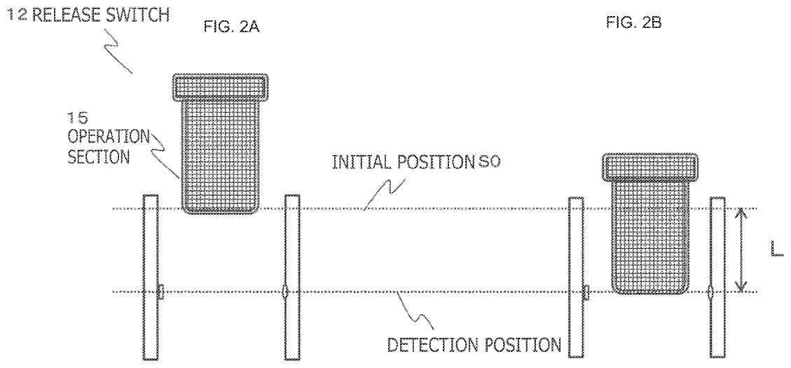

As depicted in FIG. 2, the release switch 12 includes an operation section 15. The operation section 15 is configured to be movable in a direction perpendicular to the top surface of the imaging apparatus 10 according to a depression operation of the user. As depicted in FIGS. 2(a) and 2(b), in a case where a lower end of the operation section 15 is defined as a reference for the position of the operation section 15, the lower end of the operation section 15 is located at an initial position S0 in a case where the user does not perform the depression operation, and moves from the initial position S0 in a case where the user performs the depression operation.

When a position detection section described below detects that the lower end of the operation section 15 has moved by a stroke L from the initial position S0 and arrived at a point (detection position) located at a distance L from the initial position S0, the imaging apparatus 10 executes various types of processing corresponding to the detection position. Plural detection positions can be provided in a direction perpendicular to the top surface of the imaging apparatus 10, and in that case, the imaging apparatus 10 may execute different types of processing such as AF processing and image capturing processing at the respective detection positions.

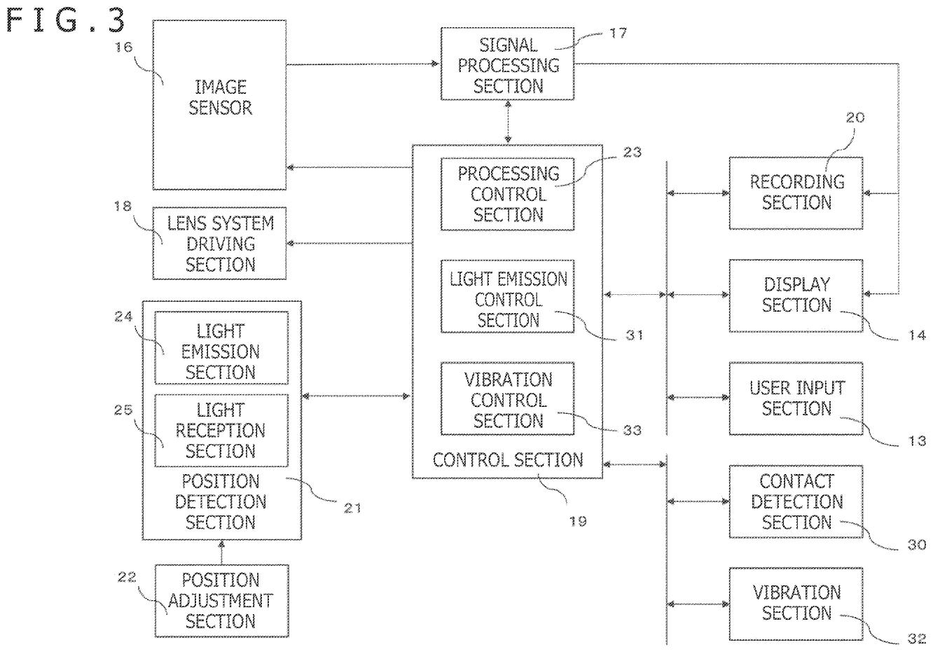

FIG. 3 is a block diagram depicting the configuration of the imaging apparatus 10. As depicted in FIG. 3, the imaging apparatus 10 includes an image sensor 16, a signal processing section 17, a lens system driving section 18, a control section 19, a recording section 20, a display section 14, a user input section 13, a position detection section 21, and a position adjustment section 22.

The image sensor 16 includes an imaging element and photoelectrically converts light traveling from a subject and collected by an optical system including a lens 11 depicted in FIG. 1. Further, the image sensor 16 executes A/D conversion processing on an electrical signal resulting from the photoelectric conversion and outputs a digital signal obtained to the signal processing section 17 as an image signal.

The position detection section 21 detects the position of the operation section 15 with respect to a detection position and outputs a detection result to the control section 19.

The control section 19 includes a processing control section 23, and on the basis of the detection result from the position detection section 21, the processing control section 23 controls each section such that the sections execute various types of processing (AF processing, image capturing processing, and the like) corresponding to the detection position.

Additionally, the control section 19 controls the sections such as the lens system driving section 18 and the display section 14.

The signal processing section 17 executes various types of signal processing such as correction processing on an image signal output from the image sensor 16 on the basis of control of the image capturing processing by the processing control section 23, and further executes, on the image signal subjected to the signal processing, processing required for recording. The signal processing section 17 outputs the image signal processed to the recording section 20. Note that the image capturing processing as used herein represents a sequence of steps of processing until the image signal subjected to the signal processing by the signal processing section 17 is output to the recording section 20.

Additionally, on the basis of control by the control section 19, the signal processing section 17 executes, on the image signal subjected to the signal processing, processing required for display, and outputs the image signal processed to the display section 14.

The lens system driving section 18 drives the lens 11 on the basis of the control of the AF processing by the control section 19.

The recording section 20 stores the image signal output from the signal processing section 17 as still image data or moving image data.

The display section 14 displays, on a screen, an image corresponding to the image signal output from the signal processing section 17.

The user input section 13 uses a button as depicted in FIG. 1 to receive an operation from the user (for example, a depression operation) related to, for example, settings for the imaging apparatus 10 (an image capturing mode, image capturing conditions, and the like), and outputs, to the control section 19, an operation signal corresponding to the operation. The control section 19 controls each section on the basis of the operation signal input. Note that the user input section 13 may be included in the display section 14 and that in that case, the display section 14 includes a touch panel function.

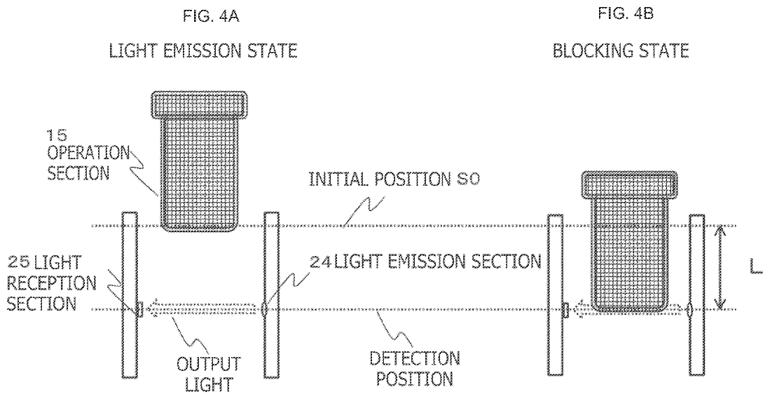

Now, processing of the release switch 12, the position detection section 21, and the processing control section 23 will be described in detail with reference to FIG. 4. The position detection section 21 detects the position of the operation section 15 and outputs a signal corresponding to the position of the operation section 15 with respect to the detection position, to the control section 19 as a detection result.

Specifically, as depicted in FIGS. 4(a) and 4(b), the position detection section 21 outputs, to the control section 19, a signal depending on whether or not a lower end of the operation section 15 has arrived at the detection position, that is, a signal indicating that the lower end has or has not arrived at the detection position.

The position detection section 21 includes a light emission section 24 and a light reception section 25, and as depicted in FIGS. 4(a) and 4(b), the light emission section 24 and the light reception section 25 are provided at the same height of the detection position (for example, the distance from the initial position S0), facing each other. The light emission section 24 is an element emitting light, for example, a LED, and the light reception section 25 receives (output) light emitted by the light emission section 24.

The light reception section 25 detects the intensity of the output light received as a current value or a voltage value (hereinafter referred to as an analog signal) and compares this detection value with a preset threshold (threshold determination). The light reception section 25 outputs a 0 signal to the control section 19 in a case where the detection value does not exceed the threshold, and outputs a 1 signal to the control section 19 in a case where the detection value exceeds the threshold (the 0 signal and the 1 signal are hereinafter referred to as digital signals).

The digital signal being the 1 signal corresponds to a state where the lower end of the operation section 15 has not arrived at the detection position, indicating a light reception state where the output light is not blocked. The digital signal being the 0 signal corresponds to a state where the lower end of the operation section 15 has arrived at the detection position, indicating a blocking state where the output light is blocked by the depression operation by the user.

In response to the input of the 0 signal, the processing control section 23 of the control section 19 executes various types of processing on the basis of the output digital signal.

Note that the position detection section 21 may include some of the functions of the processing control section 23 of the control section 19. In that case, the light reception section 25 outputs the analog signal to the control section 19, and the processing control section 23 performs the threshold determination and converts the analog signal into the digital signal.

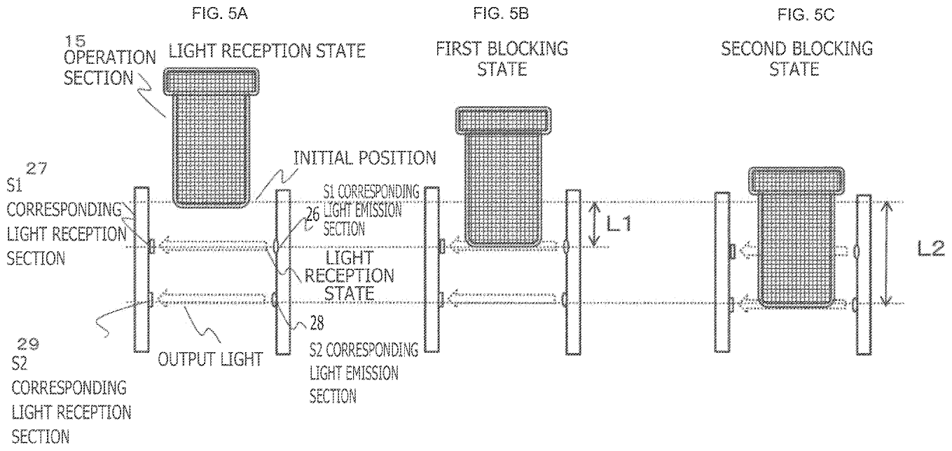

Now, with reference to FIG. 5, a case will be described in which plural detection positions are provided at different heights in a perpendicular to the top surface of the imaging apparatus 10, that is, plural pairs of the light emission section 24 and the light reception section 25 are provided and in which different types of processing are executed on the basis of the respective detection positions.

The release switch 12 is moved downward by the depression operation of the user as illustrated in FIGS. 5(a), 5(b), and 5(c).

In the downward direction in which the release switch 12 moves,

a pair of an S1 corresponding light emission section 26 and an S1 corresponding light reception section 27, and a pair of an S2 corresponding light emission section 28 and an S2 corresponding light reception section 29 are provided such that the pairs are located at respective detection positions at different heights. In other words, the pairs of the light emission section and the light reception section are provided at the same height of the detection position, facing each other.

Note that, in FIG. 5(a), each of the S1 corresponding light emission section 26 and the S2 corresponding light emission section 28 emits the output light, the output light from the S1 corresponding light emission section 26 is received by the S1 corresponding light reception section 27. The output light from the S2 corresponding light emission section 28 is received by the S2 corresponding light reception section 29 (light reception state).

In the light reception state depicted in FIG. 5(a), the lower end of the operation section 15 has not arrived at the position of the S1 corresponding light emission section 26 and the S1 corresponding light reception section 27 or at the position of the S2 corresponding light emission section 28 and the S2 corresponding light reception section 29. In this case, the processing control section 23 does not execute various types of processing because each light emission section outputs the 1 signal, corresponding to the digital signal.

Then, as depicted in FIG. 5(b), the depression operation by the user moves the operation section 15 by a stroke L1, and when arriving at a point located at a distance L1 from the initial position S0, the lower end of the operation section 15 arrives at the position of the S1 corresponding light emission section 26 and the S1 corresponding light reception section 27.

In this case, the output light from the S1 corresponding light emission section 26 is blocked by the operation section 15, and the S1 corresponding light reception section receives no light (first blocking state).

Thus, with the S1 corresponding light reception section 27 outputting the 0 signal, the processing control section 23 executes S1-on corresponding processing, for example, the autofocus (AF) processing.

Further, the user continues the processing for depressing the operation section 15, and as depicted in FIG. 5(c), the operation section 15 moves by a stroke L2, and the lower end of the operation section 15 arrives at a point located at a distance L2 from the initial position S0. Then the lower end of the operation section 15 arrives at the position of the S2 corresponding light emission section 28 and the S2 corresponding light reception section 29.

In this case, the output light from the S2 corresponding light emission section 28 is blocked by the operation section 15, and the S2 corresponding light reception section 29 receives no light (second blocking state).

Thus, with the S2 corresponding light reception section 29 outputting the 0 signal, the processing control section 23 executes S2-on corresponding processing, for example, the image capturing processing.

In the related art, a configuration is utilized in which different types of processing depending on the detection position are executed according to the depression operation of the operation section 15 of the release switch 12 by the user. However, users prefer different strokes L of the operation section 15, and when the processing is executed with a stroke L incompatible with the feeling of the user, a problem is likely to occur in that an image capturing timing intended by the user is missed. Thus, it has been desired that the user can adjust the stroke L of the operation section 15 from the initial position S0 of the operation section 15 to the detection position.

According to the configuration of the present disclosure, the user can adjust the stroke L of the operation section 15 from the initial position S0 of the operation section 15 to the detection position by using the position adjustment section 22 depicted in a block diagram in FIG. 3.

Thus, as depicted in FIG. 3, the imaging apparatus 10 of the present disclosure includes the position adjustment section 22 adjusting the stroke L of the operation section 15 from the initial position S0 of the operation section 15 to the detection position, for example, on the basis of an operation from the user. Specifically, the position adjustment section 22 adjusts the height of the detection position to adjust the stroke L. Alternatively, the position adjustment section 22 may adjust the initial position S0 of the operation section 15 to adjust the stroke L. Thus, the user can execute the various types of processing of the imaging apparatus 10 at the preferred stroke L of the user.

Note that, with plural detection positions provided, the position adjustment section 22 may be configured to be able to adjust the height of each of the detection positions to adjust the stroke L to the detection position. Additionally, the position adjustment section 22 may be configured to be able to adjust both the height of the detection position and the initial position S0 of the operation section 15 or configured to fix one of the height and the initial position S0, while being able to adjust only the other.

### 2. Configuration and Processing of Release Switch in First Example of Present Disclosure

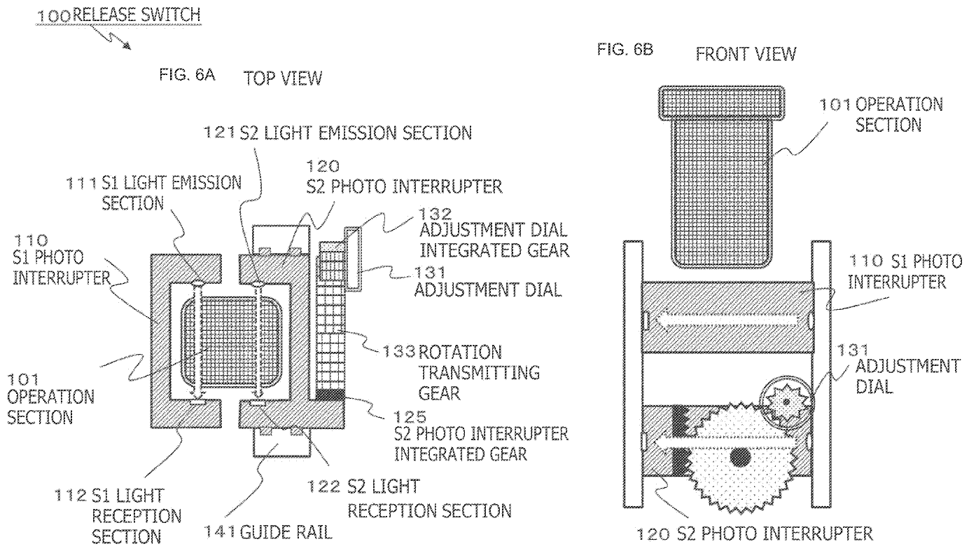

With reference to FIG. 6 and the subsequent figures, the configuration and processing of the release switch in the first example of the present disclosure will be described. The present example is an example in which the position adjustment section 22 adjusts the height of the detection position to adjust the stroke L, and the position adjustment section 22 includes an adjustment dial 131, an adjustment dial integrated gear 132, a rotation transmitting gear 133, a guide rail 141, and an S2 photo interrupter integrated gear 125 that will be described below.

FIG. 6 is a diagram depicting the configuration of a release switch 100 in the first example of the present disclosure.

(A) is a diagram of the imaging apparatus 10 as viewed from above, and

(B) is a diagram of the imaging apparatus 10 as viewed from the front.

Note that both figures depict a cross-sectional configuration of the inside of the release switch 100.

First, a central rectangular area in FIG. 6(A) corresponds to an operation section 101 that can be moved in a direction perpendicular to the top surface of the imaging apparatus 10 by the depression operation of the user. An S1 photo interrupter 110 is formed on the left of the operation section 101, and an S2 photo interrupter 120 is formed on the right of the operation section 101.

As depicted in FIG. 6(B), the two photo interrupters described above are formed on respective sides between which the operation section 101 moves up and down.

The photo interrupters 110 and 120 function as the position detection section 21 detecting the position of the operation section 101.

The photo interrupter includes a light emission section and a light reception section. In FIG. 6(A), the S1 photo interrupter 110 on the left of the operation section 101 includes an S1 light emission section 111 and an S1 light reception section 112.

Additionally, the S2 photo interrupter 120 on the right of the operation section 101 includes an S2 light emission section 121 and an S2 light reception section 122.

Note that, as depicted in a front view in FIG. 6(B), the S1 photo interrupter 110 and the S2 photo interrupter 120 are provided at detection positions at different heights.

As depicted in FIG. 6(B), in a case where the operation section 101 has not arrived at the detection position, output light from the S1 light emission section 111 of the S1 photo interrupter 110 is received by the S1 light reception section 112, and furthermore, output light from the S2 light emission section 121 of the S2 photo interrupter 120 is received by the S2 light reception section 122 (light reception state).

The processing control section 23 does not execute the various types of processing because the S1 light reception section 112 and the S2 light reception section 122 output the 1 signal.

When the operation section 101 is operationally depressed by the user, the lower end of the operation section 101 blocks the output light between the S1 light emission section 111 and the S1 light reception section 112 of the S1 photo interrupter no.

This prevents the S1 light reception section 112 from receiving the output light from the S1 light emission section 111 of the S1 photo interrupter 110.

This state corresponds to the first blocking state in FIG. 5(b).

The processing control section 23 executes the S1-on corresponding processing, for example, the autofocus (AF) processing on the basis of the 0 signal output from the S1 light reception section 112.

Further, when the operation section 101 is depressed by the user, the lower end of the operation section 101 blocks the output light between the S2 light emission section 121 and the S2 light reception section 122 of the S2 photo interrupter 120.

This also prevents the S2 light reception section 122 from receiving the output light from the S2 light emission section 121 of the S2 photo interrupter 120.

This state corresponds to the second blocking state in FIG. 5(c).

The processing control section 23 executes the S2-on corresponding processing, for example, the image capturing processing on the basis of the 0 signal output from the S2 light reception section 122.

The release switch 100 depicted in FIG. 6 is configured to be able to adjust the position (height) of the S2 photo interrupter 120.

The user can rotate the adjustment dial 131 by a direct operation and adjust the positions of the S2 light emission section 121 and the S2 light reception section 122 of the S2 photo interrupter 120 according to the rotation. The adjustment dial 131 is configured such that the adjustment dial 131 can be operated from the outside of the imaging apparatus. The adjustment dial 131 can be configured such that the adjustment dial 131 can be mechanically operated or driven, for example, by electric signals provided by user operations on a UI displayed on a display of the imaging apparatus.

The S2 photo interrupter 120 is configured to be slidable on the fixed guide rail 141 and is moved in the perpendicular direction (the same direction as the moving direction of the operation section 101) by the user by directly rotationally operating the adjustment dial 131.

Rotation of the adjustment dial 131 rotates the adjustment dial integrated gear 132, and the rotation of the adjustment dial integrated gear 132 is transmitted to the rotation transmitting gear 133 engaged with the adjustment dial integrated gear 132. Further, rotation of the rotation transmitting gear 133 is transmitted to the S2 photo interrupter integrated gear engaged with the rotation transmitting gear 133, thus adjusting the position (height) of the S2 photo interrupter 120.

Note that the amount of rotation of the rotation transmitting gear 133 is small compared to one rotation of the adjustment dial integrated gear 132 and that there is only a small amount of variation in the position (height) of the S2 photo interrupter 120 corresponding to the amount of rotation pf the adjustment dial 131. As a result, by rotating the adjustment dial 131, the user can easily and accurately adjust the position of the S2 photo interrupter 120.

Note that the position adjustment section 22 may be electrically controlled by the control section 19. For example, the user can input a rotation operation for the amount of rotation of the adjustment dial or the like via the user input section 13, and the user input section 13 outputs a signal for the rotation operation to the control section 19. The control section 19 controls the rotation processing of the adjustment dial on the basis of the output signal.

Accordingly, adjustment of position (height) of the S2 photo interrupter 120 enables adjustment of the stroke L2 of the operation section 101 required to block the output light between the S2 light emission section 121 and the S2 light reception section 122 of the S2 photo interrupter 120.

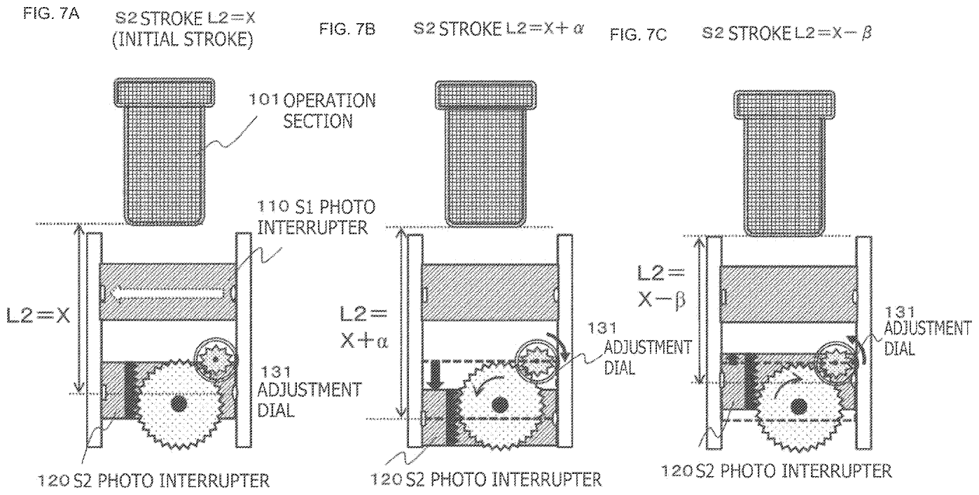

The correspondence relation between the position (height) of the S2 photo interrupter 120 and the stroke L2 of the operation section 101 will be described with reference to FIG. 7.

FIG. 7 depicts the following three examples.

S2 stroke L2=X (initial S2 stroke) (1)

S2 stroke L2=X+α (2)

S2 stroke L2=X−β (3)

(1) S2 stroke L2=X (initial S2 stroke) is a stroke obtained when the position (height) of the S2 photo interrupter 120 is not adjusted, and the initial S2 stroke of L2 is denoted as X.

(2) S2 stroke L2=X+a corresponds to an example in which the position (height) of the S2 photo interrupter 120 is moved downward (a direction away from the operation section 101), and at this time, the S2 stroke L2 is increased by a stroke a from the initial S2 stroke X.

(3) S2 stroke L2=X−β corresponds to an example in which the position (height) of the S2 photo interrupter 120 is moved upward (a direction closer to the operation section 101), and at this time, the S2 stroke L2 is reduced by a stroke 3 from the initial S2 stroke X.

Note that the strokes a and 3 may be the same value or different values.

Accordingly, the release switch 100 of the present disclosure enables the position of the S2 photo interrupter 120 to be moved up and down and allows for the S2-on corresponding processing, for example, allows adjustment of the stroke L2 of the operation section 101 for executing the image capturing processing.

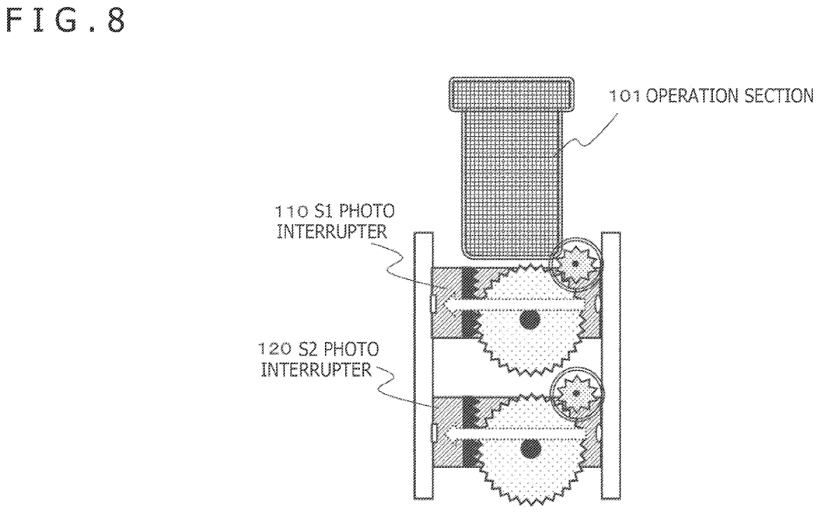

Note that the example described with reference to FIGS. 6 and 7 is a configuration example in which only the position of the S2 photo interrupter 120 is movable in the perpendicular direction but that, for example, as depicted in FIG. 8, the position of the S1 photo interrupter 110 may be movable in the perpendicular direction as well as the position of the S2 photo interrupter 120.

The configuration depicted in FIG. 8 enables adjustment of the stroke L1 of the operation section 101 in the S1-on corresponding processing as well as the stroke L2 of the operation section 101 in the S2-on corresponding processing.

### 3. Configuration and Processing of Release Switch in Second Example of Present Disclosure

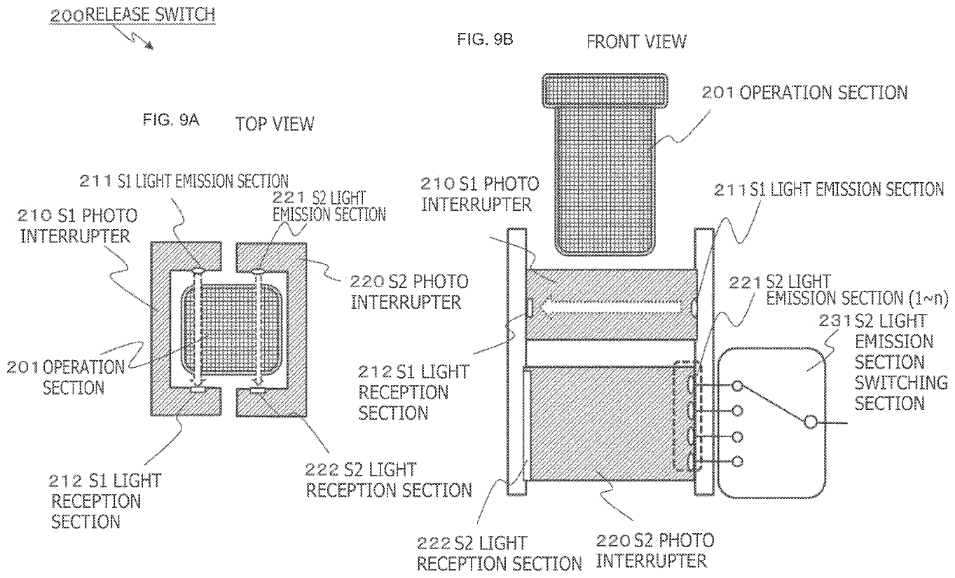

Now, with reference to FIG. 9 and subsequent figures, the configuration and processing of the release switch in the second example of the present disclosure will be described. The present example is an example in which the position adjustment section 22 adjusts the height of the detection position to adjust the stroke L, and the position adjustment section 22 includes an S2 light emission section switching section 231 described below.

FIG. 9 is a diagram depicting the configuration of a release switch 200 in the second example of the present disclosure.

(A) is a diagram of the imaging apparatus 10 as viewed from above, and

(B) is a diagram of the imaging apparatus 10 as viewed from the front.

Note that both figures depict a cross-sectional configuration of the inside of the release switch 200.

First, a central rectangular area in FIG. 9(A) corresponds to an operation section 201 that can be moved in the direction perpendicular to the top surface of the imaging apparatus by the depression operation of the user. An S1 photo interrupter 210 is formed on the left of the operation section 201, and an S2 photo interrupter 220 is formed on the right of the operation section 201.

As depicted in FIG. 9(B), the two photo interrupters described above are formed on respective sides between which the operation section 201 moves up and down.

The photo interrupters 210 and 220 function as the position detection section 21 detecting the position of the operation section 101.

The S1 photo interrupter 210 on the left of the operation section 201 includes an S1 light emission section 211 and an S1 light reception section 212.

Additionally, the S2 photo interrupter 220 on the right of the operation section 201 includes an S2 light emission section 221 and an S2 light reception section 222.

In the present example, as depicted in a front view in FIG. 9(B), the S2 photo interrupter 220 includes plural (n) light emission sections (1 to n) provided at different heights of detection positions. The user can switch on and off light emission from each light emission section via the user input section 13, and the control section 19 controls the switching processing of the light emission section switching section on the basis of a switching signal output from the user input section 13.

Plural (n) S2 light emission sections (1 to n) 221 of the S2 photo interrupter 220 in the present example have a switch configuration in which the S2 light emission section switching section 231 can switch on and off light emission from the S2 light emission sections 221, and by switching light emission from the plural (n) light emission sections (1 to n) provided at different heights of the detection positions, the height of the detection position can be adjusted.

As described above, switching on and off light emission from the light emission sections set at detection positions at different heights enables adjustment of the stroke L2 of the operation section 201 required to block the output light between the S2 light emission section 221 and the S2 light reception section 222 of the S2 photo interrupter 220.

For example, in a case where the uppermost (the position closest to the operation section 201) one of the plural (n) S2 light emission sections 221 of the S2 photo interrupter 220 is caused to emit light, this allows setting, to a small value, of the stroke L2 of the operation section 201 required to block the output light between the S2 light emission section 221 and the S2 light reception section 222 of the S2 photo interrupter 220.

On the other hand, in a case where the lowermost (the position farthest from the operation section 201) one of the plural (n) S2 light emission sections 221 of the S2 photo interrupter 220 is caused to emit light, this allows setting, to a large value, of the stroke L of the operation section 201 required to block the output light between the S2 light emission section 221 and the S2 light reception section 222 of the S2 photo interrupter 220.

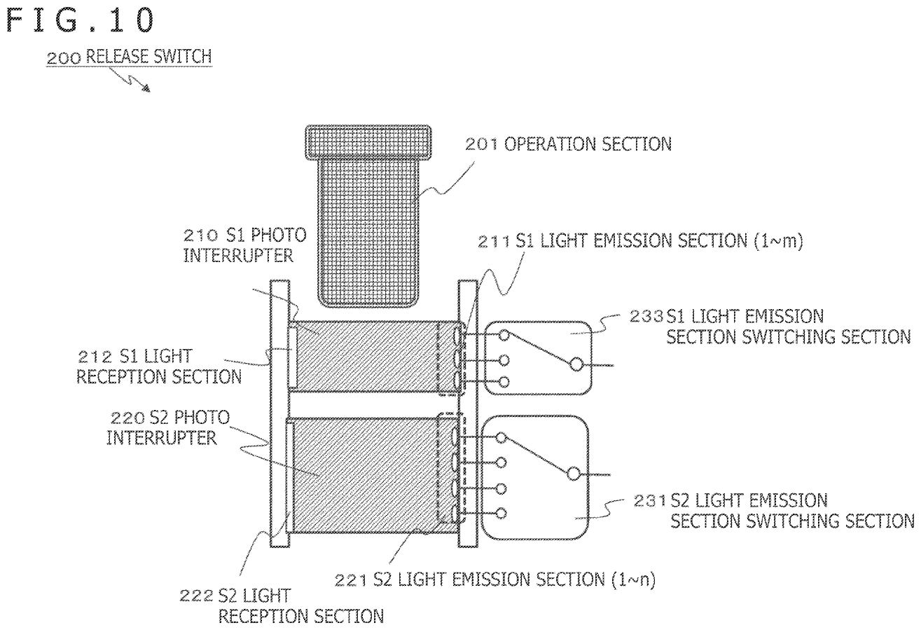

Note that the example illustrated with reference to FIG. 9 is an example in which only the S2 photo interrupter 220 includes the plural (n) light emission sections but that, for example, as depicted in FIG. 10, the S1 photo interrupter 210 may include S1 light emission sections (1 to m) 211 including plural (m) light emission sections as well as the S2 photo interrupter 220, and that as is the case with the S2 photo interrupter 220, the height of the detection position can be adjusted by using the light emission section switching section to switch on and off light emission from each light emission section.

The configuration as depicted in FIG. 10 enables adjustment of the stroke L1 of the operation section 101 in the S1-on corresponding processing as well as the stroke L2 of the operation section 101 in the S2-on corresponding processing.

### 4. Configuration and Processing of Modified Example of Release Switch in Second Example of Present Disclosure

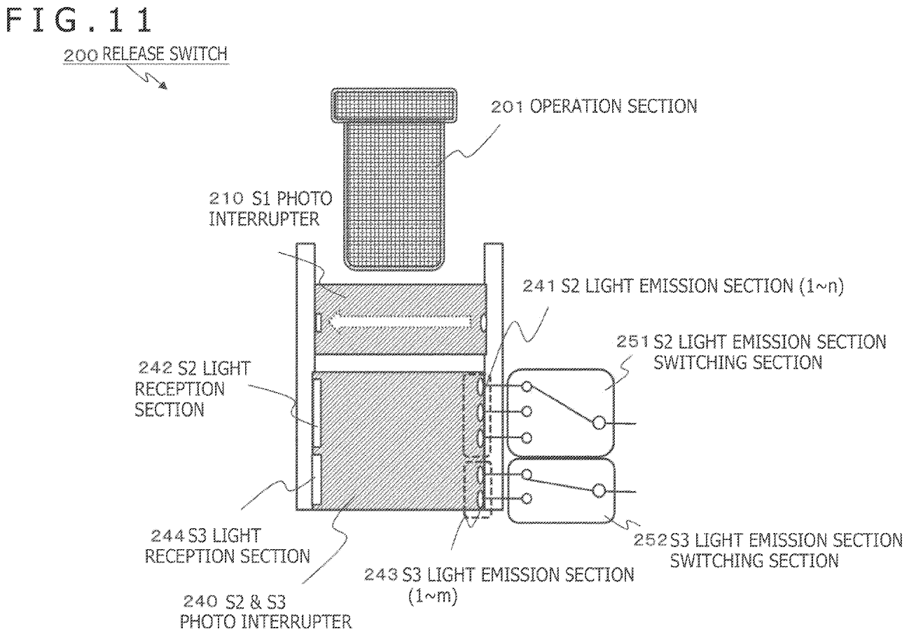

Now, with reference to FIG. 11 and subsequent figures, the configuration and processing of a modified example of the release switch in the second example of the present disclosure will be described.

FIG. 11 is a diagram depicting the configuration of the modified example of the release switch 200 in the second example of the present disclosure.

In the release switch 200 depicted in FIG. 11, the S2 photo interrupter 220 of the release switch 200 in the second example described above with reference to FIG. 9 is changed to an S2 & S3 photo interrupter 240 depicted in FIG. 11. For the S1-on corresponding processing, the S2-on corresponding processing, and S3-on corresponding processing, execution of each type of processing based on movement of the operation section 201 will be described.

When the operation section 201 of the release switch 200 depicted in FIG. 11 is depressed by the user, first, the lower end of the operation section 201 blocks the output light between the S1 light emission section 211 and the S1 light reception section 212 of the S1 photo interrupter 210.

This prevents the S1 light reception section 212 from receiving the output light from the S1 light emission section 211 of the S1 photo interrupter 210.

With the S1 light reception section 212 outputting the 0 signal, the processing control section 23 executes the S1-on corresponding processing, for example, the autofocus (AF) processing.

Further, when the operation section 201 is depressed by the user, the lower end of the operation section 201 also blocks the output light between an S2 light reception section 242 and one of plural (n) S2 light emission sections (1 to n) 241 of the S2 & S3 photo interrupter 240 which light emission section 241 is switched to emit light.

This prevents the S2 light reception section 242 from receiving output light from the one of the plural (n) S2 light emission sections (1 to n) 241 of the S2 & S3 photo interrupter 240 which light emission section 241 is switched to emit light.

With the S2 light reception section 242 outputting the 0 signal, the processing control section 23 executes the S2-on corresponding processing, for example, the image capturing processing.

Further, when the operation section 201 is depressed by the user, the operation section 201 also blocks the output light between an S3 light reception section 244 and one of plural (m) S3 light emission sections (1 to m) 243 of the S2 & S3 photo interrupter 240 which light emission section 243 is switched to emit light.

This prevents the S3 light reception section 244 from receiving output light from the one of the plural (m) S3 light emission sections (1 to m) 243 of the S2 & S3 photo interrupter 240 which light emission section 243 is switched to emit light.

With the S3 light reception section 244 outputting the 0 signal, the processing control section 23 executes the S3-on corresponding processing.

Note that the S3-on corresponding processing corresponds to, for example, continuous shooting processing, moving image capturing processing, reproduction processing for captured images, high-quality image recording processing for HDR images and the like, image correction such as white balance adjustment, and any other type of processing, and that these types of processing can be preset by the user.

Note that, for the processing other than the S3-on corresponding processing, that is, for the S1-on corresponding processing and the S2-on corresponding processing as well, the user can preset what processing is to be executed. The examples of the S3-on corresponding processing listed above are only illustrative, and the user can also freely set combinations of the S1-on corresponding processing, the S2-on corresponding processing, and the S3-on corresponding processing.

In the configuration illustrated in FIG. 11, the user can switch on and off light emission from each of the light emission sections of an S2 light emission section switching section 251 and an S3 light emission section switching section 252 via the user input section 13, and the control section 19 controls the switching processing of each light emission section switching section on the basis of a switching signal output from the user input section 13.

The configuration as described above enables the user to adjust the strokes L2 and L3 of the operation section 201 for the S2-on corresponding processing and the S3-on corresponding processing.

Note that, in the configuration depicted in FIG. 11, the S2 & S3 photo interrupter 240 is provided with the S2 light emission sections (1 to n) 241 and the S2 light reception section 242, and the S3 light emission sections (1 to m) 243 and the S3 light reception section 244, and these components are provided in proximity to one another.

Consequently, for example, even in a case where the operation section 201 is located at the height of the S2 light emission sections (1 to n) 241 and the S2 light reception section 242 to prevent the S2 light reception section 242 from receiving output light from one of the S2 light emission sections (1 to n) 241 which light emission section is switched to emit light, output light from the S3 light emission sections (1 to m) 243 may be received from the S2 light reception section 242. In such a case, an error may occur.

To prevent such an error, the light emission elements in the S2 light emission sections (1 to n) 241 and the S3 light emission sections (1 to m) 243 preferably include light emission elements outputting light with high directionality.

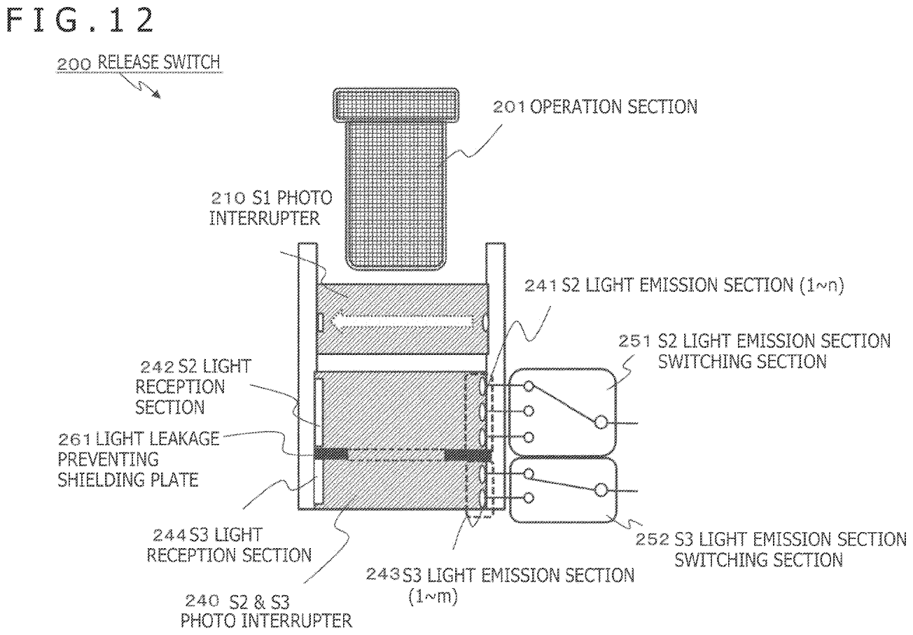

Further, as depicted in FIG. 12, the configuration may be provided with a light leakage preventing shielding plate 261.

The configuration depicted in FIG. 12 is provided with a light leakage preventing shielding plate 261 between the S2 light emission sections (1 to n) 241 and the S3 light emission sections (1 to m) 243 and a light leakage preventing shielding plate 261 between the S2 light reception section 242 and the S3 light reception section 244.

Setting of the shielding plates as described above reduces the possibility that light from the S3 light emission sections (1 to m) 243 is received from the S2 light reception section 242, enabling prevention of possible errors.

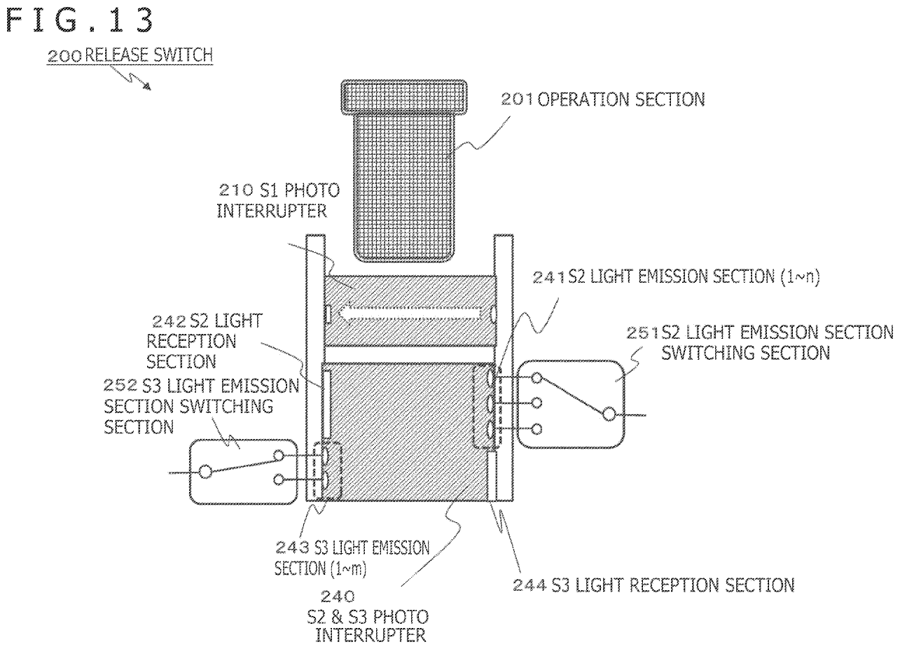

Alternatively, as depicted in FIG. 13, another effective configuration for preventing erroneous reception of light is a configuration in which the set of the S2 light emission sections (1 to n) 241 and the set of the S3 light emission sections (1 to m) 243 are installed at opposing positions and in which the S2 light reception section 242 and the S3 light reception section 244 are installed at opposing positions, and thus the configuration depicted in FIG. 13 may be provided.

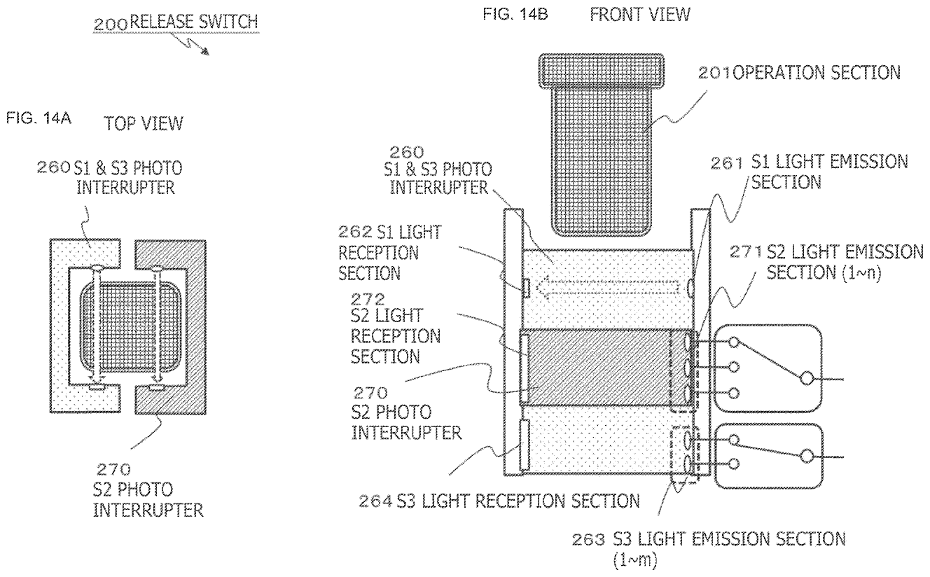

Further, a configuration depicted in FIG. 14 is also an effective configuration for preventing erroneous reception of light.

FIG. 14 depicts:

(A) a diagram of the imaging apparatus 10 as viewed from above, and

(B) a diagram of the imaging apparatus 10 as viewed from the front.

Note that both figures depict a cross-sectional configuration of the inside of the release switch 200.

In the configuration depicted in FIG. 14, as depicted in the top view in (A), an S1 & S3 photo interrupter 260 is formed on the left of the operation section 201, and an S2 photo interrupter 270 is formed on the right of the operation section 201.

As depicted in a front view in FIG. 14(B), the set of the S1 light emission section 261 and the S1 light reception section 262 and the set of the S3 light emission sections (1 to m) 263 and the S3 light reception section 264 are installed at different heights of detection positions in the S1 & S3 photo interrupter 260.

Additionally, the S2 light emission section (1 to n) 271 and the S2 light reception section 272 are installed on the S2 photo interrupter 270.

This configuration allows the three pairs of the light emission section and the light reception section to be spaced apart from one another, enabling a reduction in erroneous light reception processing.

### 5. Third Example—Power Saving Type Example

Now, as Example 3, an example of the release switch of the present disclosure with power saving implemented will be described.

Note that Example 3 described below is an example that is available for all of Examples 1 and 2 described above.

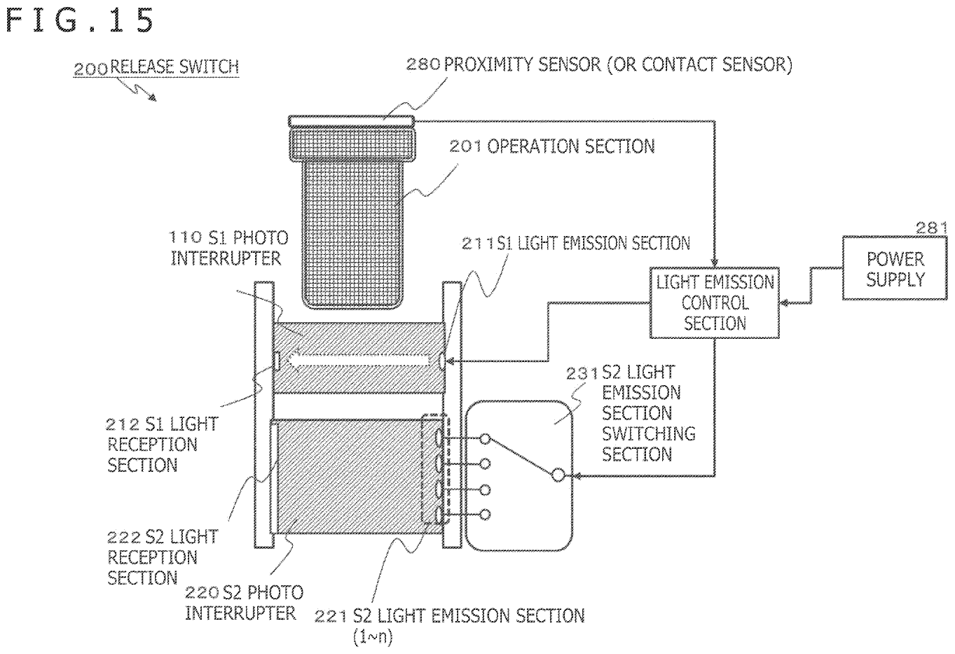

FIG. 15 depicts an example in which a power saving configuration is applied to the release switch 200 in Example 2 described above with reference to FIG. 9.

Example 1 and Example 2 described above correspond to a configuration that executes various type of processing according to blocking of output light from the light emission section resulting from depression of the operation section.

In this configuration, the light emission section needs to continuously output light, and this is not preferable in terms of power consumption.

The configuration depicted in FIG. 15 solves such a problem to reduce power consumption. In this case, the imaging apparatus 10 depicted in FIG. 3, the operation section 15 includes a contact detection section 30, and furthermore, the control section 19 includes a light emission control section 31. The light emission control section 31 controls light emission from the light emission section according to detection information from the contact detection section 30. At an upper end of the operation section 201 of the release switch 200 depicted in FIG. 15, a proximity sensor (or a contact sensor) 280 used as the contact detection section 30 is installed to detect contact of the user with the operation section 15 or approach of the user to the operation section 15. This will be described below in detail.

The proximity sensor (or the contact sensor) 280 used as the contact detection section 30 detects that the finger of the user has approached or contacted the upper end of the operation section 201 and outputs, to the light emission control section 31 of the control section 19, a signal corresponding to the detection.

On the basis of this signal, the light emission control section 31 controls processing for supplying power to the light emission section. In a case where the finger of the user approaches or contacts the upper end of the operation section 201, the light emission control section 31 supplies the light emission sections, that is, the S1 light emission section 211 and the S2 light emission section 221 with power supplied from a power supply 281. The power supply processing causes the S1 light emission section 211 and the S2 light emission section 221 to emit light.

In a case where the finger of the user does not approach or contact the upper end of the operation section 201, the S1 light emission section 211 and the S2 light emission section 221 emit no light, enabling a resultant reduction in power consumption.

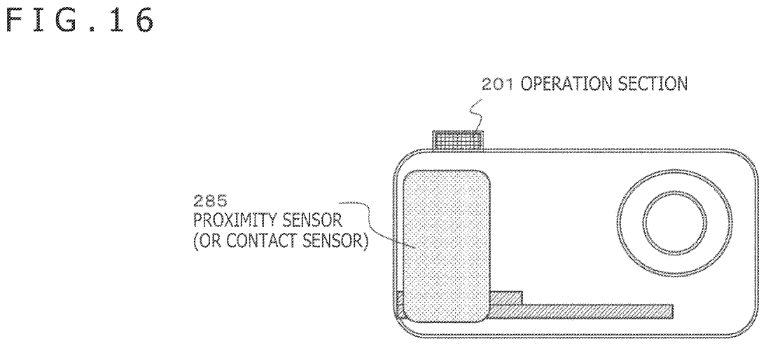

Note that the contact detection section 30 need not be formed in the operation section 201. For example, as depicted in FIG. 16, a proximity sensor (or a contact sensor) 285 may be provided in a grip portion of the imaging apparatus.

In the configuration depicted in FIG. 16, the proximity sensor (or the contact sensor) used as the contact detection section 30 detects that, for example, the user has held the imaging apparatus in the hand, enabling the S1 light emission section 211 or the S2 light emission section 221 to emit light.

### 6. Forth Example—Example with Processing Notification Function

Now, as Example 4, an example of the release switch of the present disclosure including a processing notification function will be described.

Example 4 described below is also an example that is available for all of the examples described above.

As described in Examples 1 and 2, the imaging apparatus of the present disclosure executes different types of processing at plural detection positions. For example, when the operation section 15 is depressed to prevent the light reception section from receiving the output light from the light emission section of the S1 photo interrupter, the AF processing is executed as the S1-on corresponding processing.

Further, when the depression of the operation section 15 prevents the light reception section from receiving the output light from the light emission section of the S2 photo interrupter, the image capturing processing is executed as the S2-on corresponding processing.

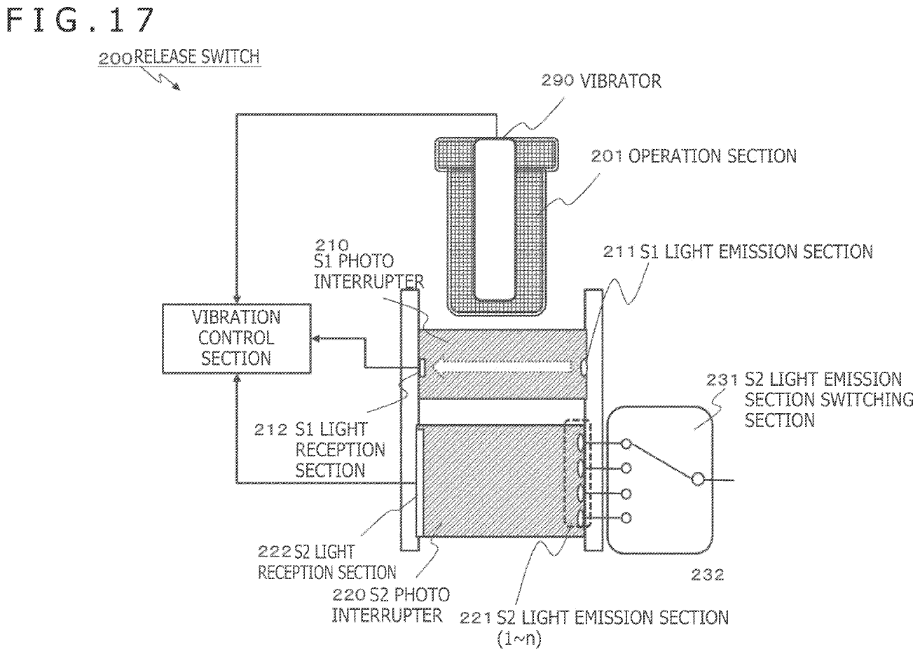

The example described below is an example in which a function is provided to notify the user of processing being executed in the imaging apparatus. In this case, in the imaging apparatus 10 depicted in FIG. 3, the operation section 15 includes a vibration section 32, and furthermore, the control section 19 includes a vibration control section 33. The vibration control section 33 controls vibration processing of the vibration section 32 on the basis of a digital signal output from the position detection section 21. As depicted in FIG. 17, the operation section 201 of the release switch 200 includes a built-in vibrator 290 used as the vibration section 32.

The vibrator 290 used as the vibration section 32 performs various different types of vibrations, under the control of the vibration control section 33 of the control section 19.

As depicted in FIG. 17, the vibration control section 33 receives digital signals respectively output from the S1 light reception section 212 of the S1 photo interrupter 210 and the S2 light reception section 222 of the S2 photo interrupter 220.

The vibration control section 33 vibrates the vibrator 290 in a predetermined vibration mode on the basis of the 0 signal output from the S1 light reception section 212 of the S1 photo interrupter 210. This vibration timing is synchronous with an execution timing for the S1-on corresponding processing (AF processing or the like) executed by the control section.

The user perceives the vibration with the finger in contact with the operation section 201 and can recognize that the S1-on corresponding processing (AF processing or the like) is being executed.

Further, the vibration control section 33 vibrates the vibrator 290 in a predetermined vibration mode on the basis of the 0 signal output from the S2 light reception section 222 of the S2 photo interrupter 220. This vibration timing is synchronous with an execution timing for the S2-on corresponding processing (image capturing processing or the like) executed by the control section.

The user perceives the vibration with the finger in contact with the operation section 201 and can recognize that the S2-on corresponding processing (image capturing processing or the like) is being executed.

Note that the vibration control section 33 can vibrate the vibrator 290 in different vibration modes depending on whether the S1-on corresponding processing or the S2-on corresponding processing is executed. For example, the magnitude of the vibration or the time intervals of the vibration is adjusted to vary depending on whether the S1-on corresponding processing or the S2-on corresponding processing is executed.

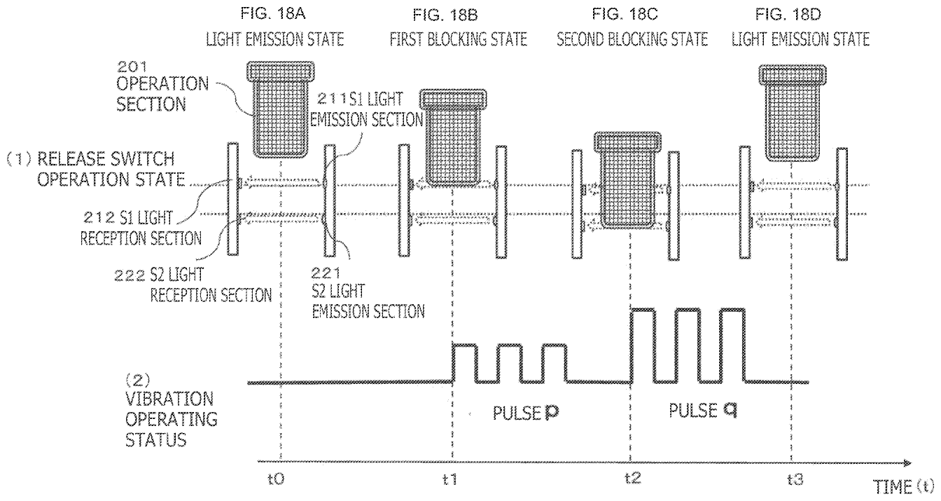

A specific example will be described with reference to FIG. 18.

FIG. 18 illustrates the following information along the time axis:

(1) a release switch operation state, and

(2) a vibration operation state.

For example, in a specific example in FIG. 18, the (a) light reception state, the (b) first blocking state, the (c) second blocking state, and the (d) light reception state are realized by the depression operation of the user in a sequence of flows. During the (b) first blocking state at time t1, the S1 light reception section 212 of the S1 photo interrupter 210 outputs the 0 signal, and the vibration control section 33 vibrates the vibrator 290 in a vibration mode according to the waveform of a pulse p as depicted in FIG. 18.

The user perceives the vibration according to the pulse p with the finger in contact with the operation section 201 and can recognize that the S1-on corresponding processing (AF processing or the like) is being executed.

Further, during the (c) second blocking state at time t2, the S2 light reception section 222 of the S2 photo interrupter 220 outputs the 0 signal, and the vibration control section 33 vibrates the vibrator 290 in a vibration mode according to the waveform of a pulse q as depicted in FIG. 18.

The user perceives the vibration according to the pulse q with the finger in contact with the operation section 201 and can recognize that the S2-on corresponding processing (image capturing processing or the like) is being executed.

As described above, the vibration control section 33 can vibrate the vibrator 290 in different vibration modes depending on whether the S1-on corresponding processing or the S2-on corresponding processing is executed. Thus, the user can recognize the execution timing and type of the processing being executed in the imaging apparatus.

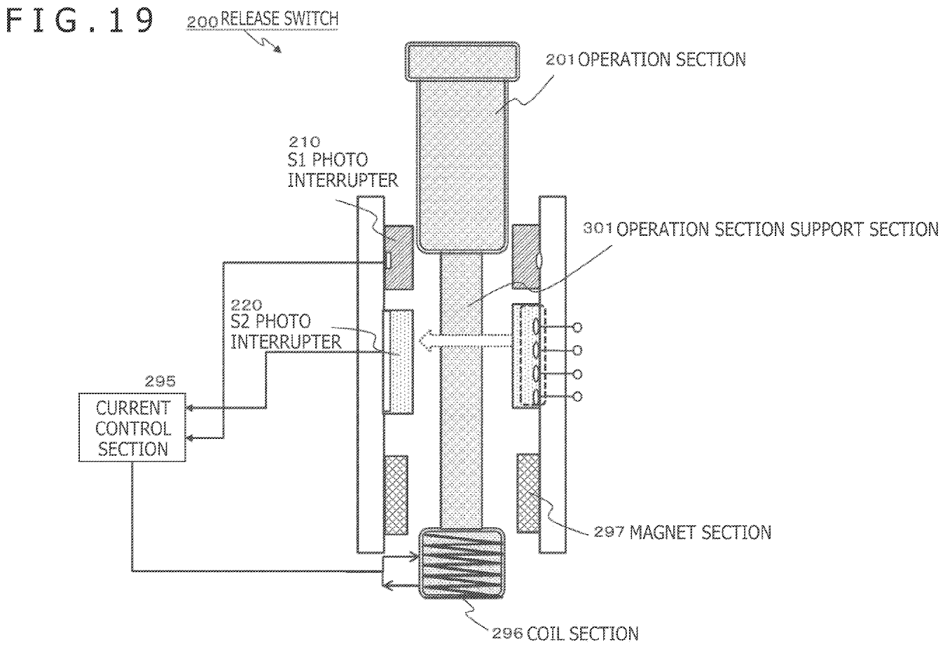

An example described with reference to FIG. 19 and subsequent figures is an example in which the imaging apparatus includes a function enabling the user to adjust a repulsive force (weight and load) when the user depresses the release switch. In the present example, the imaging apparatus 10 in FIG. 3 includes a repulsion section not depicted in the drawings, and furthermore, the control section 19 includes a current control section 295. The repulsion section includes a coil section 296 and a magnet section 297. The current control section 295 controls a current (direct current) passed through the coil section 296, on the basis of the digital signal output from the position detection section 21.

As depicted in FIG. 19, the coil section 296 is provided in an operation section support section 301 of the release switch 200, and the magnet section 297 is provided at the bottom of the S2 photo interrupter in a ring shape. The current control section 295 receives digital signals respectively output from the S1 light reception section 212 of the S1 photo interrupter 210 and the S2 light reception section 222 of the S2 photo interrupter 220. Note that the magnet section 297 need not be in a ring shape and that, for example, separate magnets may be provided in four directions surrounding the operation instruction section 301 as viewed from above, with the shape of the magnet section 297 not being limited. Additionally, the coil section 296 may internally contain an iron core, which can enhance magnetic fields.

The current control section 295 passes a current r through the coil section 296 on the basis of the 1 signal output from the S1 light reception section 212 of the S1 photo interrupter 210. When the current r flows through the coil section 296, magnetic fields are generated and cause a repulsive force to be exerted in the magnet section 297 in the perpendicular direction. At this time, with a current flowing through the coil section 296 clockwise as viewed from above, an upward repulsive force is generated in the magnet section 297, including a ring-like inner portion formed as an S pole and a ring-like outer portion formed as an N pole.

Then, the current control section 295 passes a current s through the coil section 296 on the basis of the 0 signal output from the S1 light reception section 212 of the S1 photo interrupter 210. The current s flowing through the coil section 296 changes the repulsive force generated upward.

Further, the current control section 295 stops the current flowing through the coil section 296 on the basis of the 0 signal output from the S2 light reception section 222 of the S2 photo interrupter 220. When no current flows through the coil section 296, generation of a repulsive force is stopped.

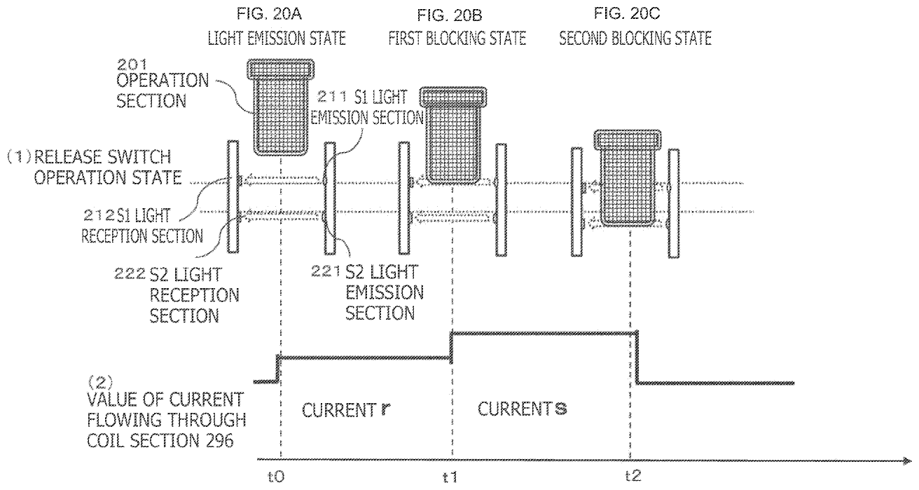

In this regard, FIG. 20 illustrates the following information along the time axis:

(1) a release switch operation state, and

(2) the value of a current flowing through the coil section 296.

The current control section can generate different repulsive forces depending on whether the operation section depressed starts from the initial position (S0) and arrives at the position of the S1 photo interrupter 210 or starts from the position of the S1 photo interrupter 210 and arrives at the position of the S2 photo interrupter 220. For example, by varying the magnitude of the current (current value) between the current r and the current s, the magnitude of the repulsive force can be adjusted to vary depending on whether the operation section depressed starts from the initial position (S0) and arrives at the position of the S1 photo interrupter 210 or starts from the position of the S1 photo interrupter 210 and arrives at the position of the S2 photo interrupter 220.

For example, in a specific example in FIG. 20, the (a) light reception state, the (b) first blocking state, the (c) second blocking state, and the (d) light reception state are realized by the depression operation of the user in a sequence of flows. During the (a) light reception state at time t0, the S1 light reception section 212 of the S1 photo interrupter 210 outputs the 1 signal to the current control section 295, passing the current r through the coil section 296. At this time, the current r is 2 mA (milliamperes).

During the (b) first blocking state at time t1, the S1 light reception section 212 of the S1 photo interrupter 210 outputs the 0 signal, and the current control section 295 passes the current s through the coil section 296. At this time, the current s is 5 mA.

Further, during the (c) second blocking state at time t2, the S2 light reception section 222 of the S2 photo interrupter 220 outputs the 0 signal, and the current control section 295 stops the current flowing through the coil section 296. By varying the magnitude of the current (current value) flowing through the coil section 296, different repulsive forces can be generated depending on whether the operation section depressed starts from the initial position (S0) and arrives at the position of the S1 photo interrupter 210 or starts from the position of the S1 photo interrupter 210 and arrives at the position of the S2 photo interrupter 220. Note that the current passed through the coil section 296 may be controlled by pulse width modulation control (Pulse Width Modulation, PWM) or that with a voltage value constant, a duty ratio may be varied to vary the current value.

Note that the user can optionally set, via the user input section 13, the magnitude of the current (current value), the timing when the current is passed, the time intervals at which the current is passed, and the like. Additionally, in a case where the S3 photo interrupter is provided, the current control section 295 may adjust the repulsive force applied when the operation section depressed starts from the position of the S2 photo interrupter 220 and arrives at the S3 photo interrupter by, for example, passing a current of 10 mA when the S2 light reception section 222 of the S2 photo interrupter 22—outputs the 0 signal.

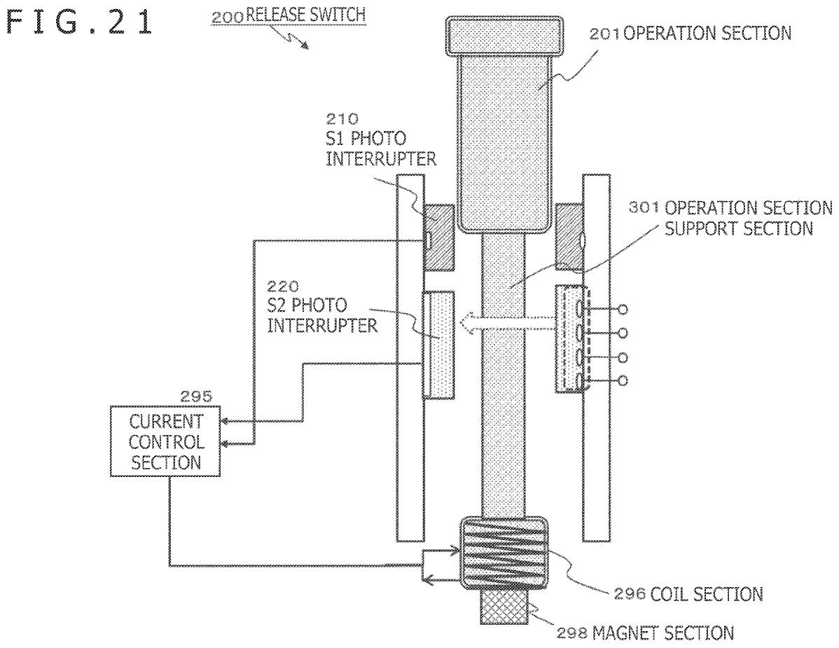

Additionally, in another configuration, the coil section 296 and a magnet section 298 may be provided in an operation section support section 330 as depicted in FIG. 21. In this case, the magnet section 298 is provided at the top of the coil section 296, and is in a cylindrical shape and includes an S pole in the upper portion and an N pole in the lower portion. The current flows through the coil section 296 counterclockwise as viewed from above to generate a repulsive force upward. Note that the magnet section 298 need not be in a ring shape and that the shape of the magnet section 298 is not limited.

Additionally, in the present example, the configuration includes the coil section and the magnet section, and the current is passed through the coil section to generate repulsive force repelling the magnet section. However, the magnet section may include a permanent magnet and a yoke. The example illustrated in FIG. 19 needs to be configured such that the magnet section includes the S pole in the inner portion and the N pole in the outer portion in order to generate a repulsive force upward in view of the direction of magnetic fields generated by the coil section. However, when the yoke is provided to form a magnetic circuit, the direction of the magnetic fields can be controlled, enabling design in which the configuration of the magnet section is not limited, for example, the magnet section includes the S pole in the upper portion and the N pole in the lower portion.

### 7. Operation Section Holding Mechanism and Example of Adjustment Configuration for Initial Position (S0)

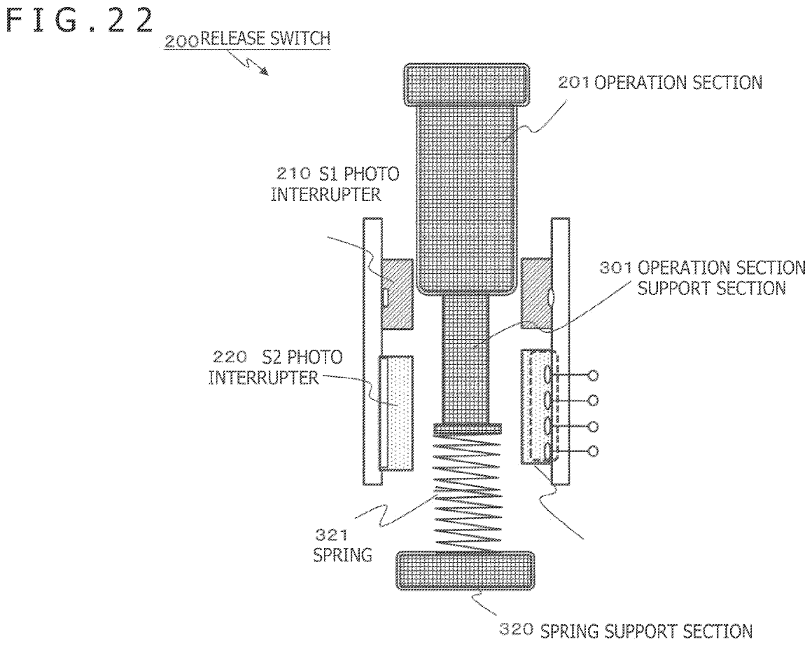

Now, an operation section holding mechanism and an example of an adjustment configuration for the initial position (S0) will be described with reference to FIG. 22.

A configuration described below can be applied to all of the examples described above.

As described above in the examples, the release switch of the present disclosure is configured such that the operation section 15 blocks the output light from the light emission section 24 and the light reception section 25, and on the basis of the 0 signal output from the light reception section 25, the processing control section 23 executes various types of processing (AF processing, image capturing processing, and the like).

In this regard, in the present example, a configuration will be described in which the lower end of the operation section 15 having arrived at the detection position corresponding to the S1-on corresponding processing or the S2-on corresponding processing due to the depression operation of the user returns to the initial position S0. This configuration example is depicted in FIG. 22.

As depicted in FIG. 22, the operation section support section 301 is formed integrally at the bottom of the operation section 201. A lower end of the operation section support section 301 is fixed to an upper end of a spring 321 fixed to a spring support section 320.

This configuration enables the operation section 201 to return to the initial position S0 when the user releases depression.

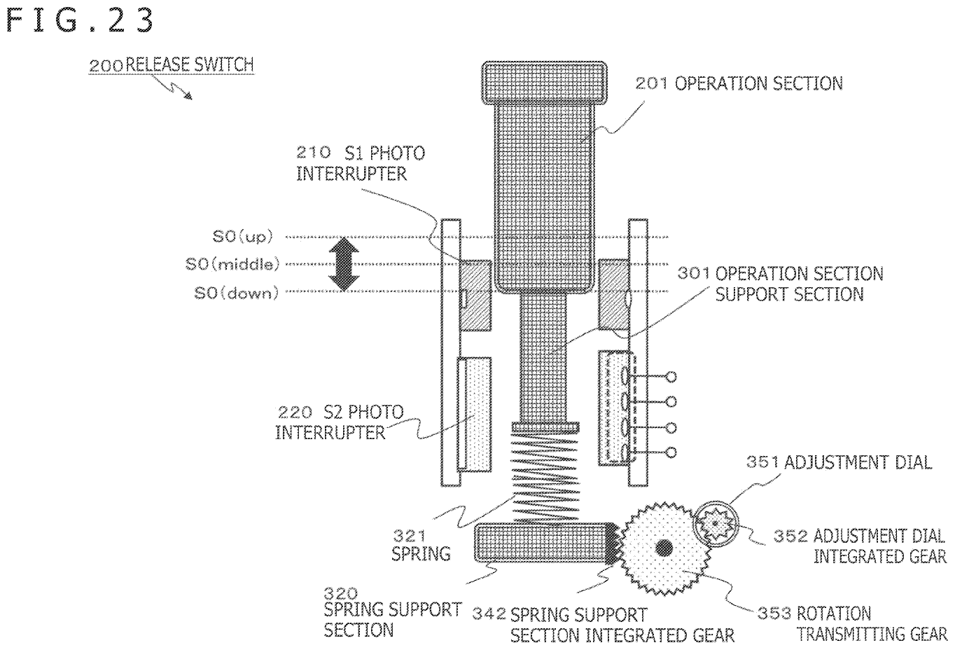

In this regard, with reference to FIG. 23, a configuration will be described that can adjust the initial position S0 when the above-described stroke L of the operation section 15 from the initial position S0 to the detection position is adjusted. The position adjustment section 22 in the present example includes an adjustment dial 351, the spring support section 320, the spring 321, a spring support section integrated gear 342, an adjustment dial integrated gear 352, and a rotation transmitting gear 353.

As depicted in FIG. 23, the user directly rotationally operated the adjustment dial 351 to rotate the adjustment dial integrated gear 352, and this rotation rotates the rotation transmitting gear 353, and furthermore, the rotation of the rotation transmitting gear 353 is transmitted to the spring support section integrated gear 342 integrated with the spring support section 320, which is thus moved in an up-down direction.

Moving the spring support section 320 in the up-down direction also moves the lower end of the operation section 201 from S0 (up) through S0 (middle) to S0 (down) as depicted in FIG. 23.

In other words, the user operates the adjustment dial 351 to enable the initial position S0 to be adjusted.

Note that the position adjustment section 22 may be electrically controlled by the control section 19. For example, the user can input a rotation operation for the amount of rotation of the adjustment dial or the like via the user input section 13, and the user input section 13 outputs a signal for the rotation operation to the control section 19. The control section 19 controls rotation processing of the adjustment dial on the basis of the output signal.

### 8. Configuration and Processing of Release Switch in Fifth Example of Present Disclosure

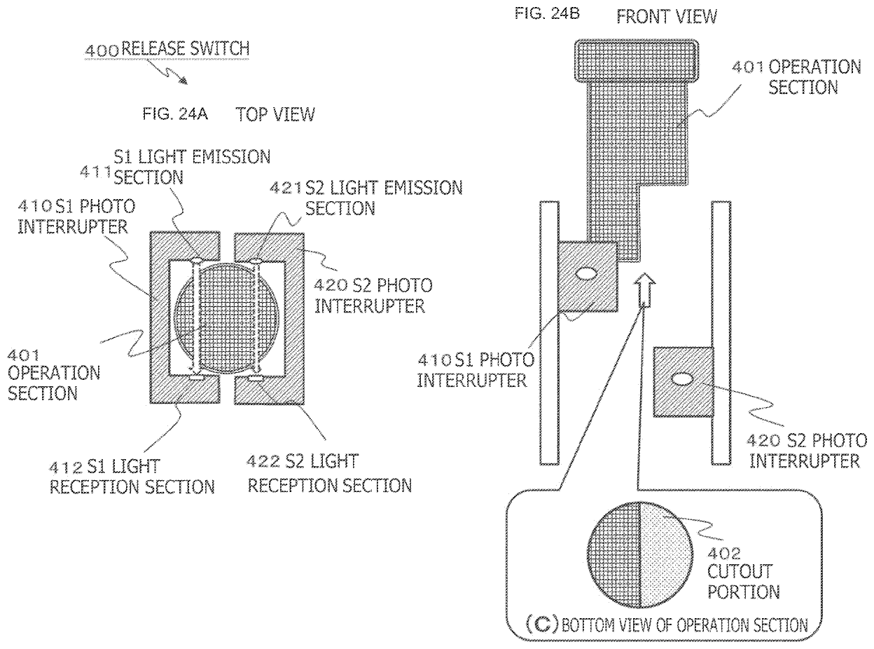

Now, the configuration and processing of a release switch in a fifth example of the present disclosure will be described with reference to FIG. 24 and subsequent figures. The present example is an example in which the position adjustment section 22 adjusts the initial position S0 of the operation section 15 to adjust the stroke L, and the position adjustment section 22 includes a cutout portion 402.

FIG. 24 is a diagram depicting the configuration of a release switch 400 in the fifth embodiment of the present disclosure.

(A) is a diagram of the imaging apparatus 10 as viewed from above,

(B) is a diagram of the imaging apparatus 10 as viewed from above, and

(C) is a bottom view of the operation section.

Note that both the top view in (A) and the front view in (B) are diagrams depicting a cross-sectional configuration of the inside of the release switch 400.

In the present example, as depicted in the front view in FIG. 24(B) and the bottom view of an operation section in FIG. 24(C), an operation section 401 is cylindrical and includes the cutout portion 402 located at the bottom and shaped like a semi-circle.

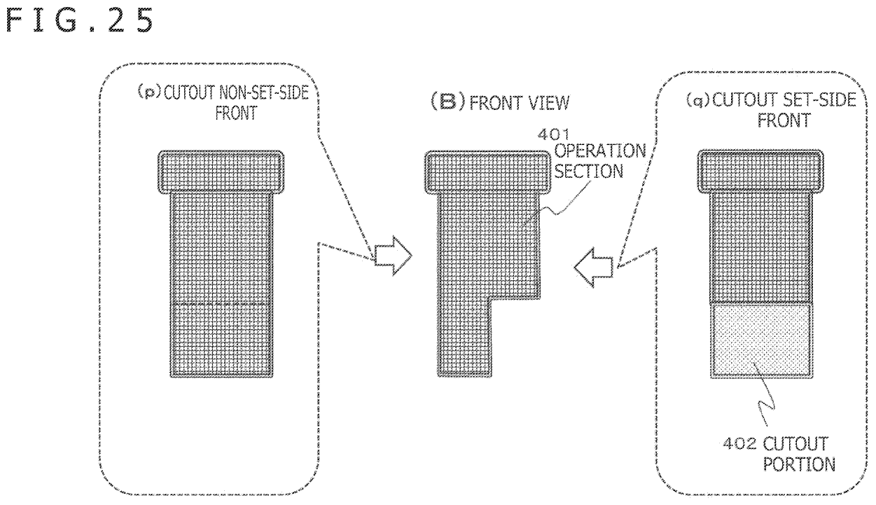

With reference to FIG. 25, the configuration of the operation section 401 will be described. In the center of FIG. 25, (B) front view of the operation section 401 as viewed in a direction similar to the direction depicted in FIG. 24 is depicted. A (p) cutout non-set side front depicted on the left of FIG. 25 is a diagram of the operation section 401 as observed from the left of (B) front view. The cutout portion 402 is not set on this semi-circular side.

On the other hand, a (q) cutout set side front depicted on the right of FIG. 25 is a diagram of the operation section 401 as observed from the right of (B) front view. The cutout portion 402 is set on this semi-circular side. In this case, the length of a long side of the cutout portion 402 is denoted as a.

The cutout portion can be moved, by a rotation operation of the user, around a rotation axis extending through the operation section 401 in the perpendicular direction. The rotation axis in the present example corresponds to an axis extending through the center of a circle corresponding to the shape of the operation section 401 as viewed from the top surface of the operation section 401.

The present example is an example in which the user rotates the operation section 401 to enable the stroke L to be adjusted.

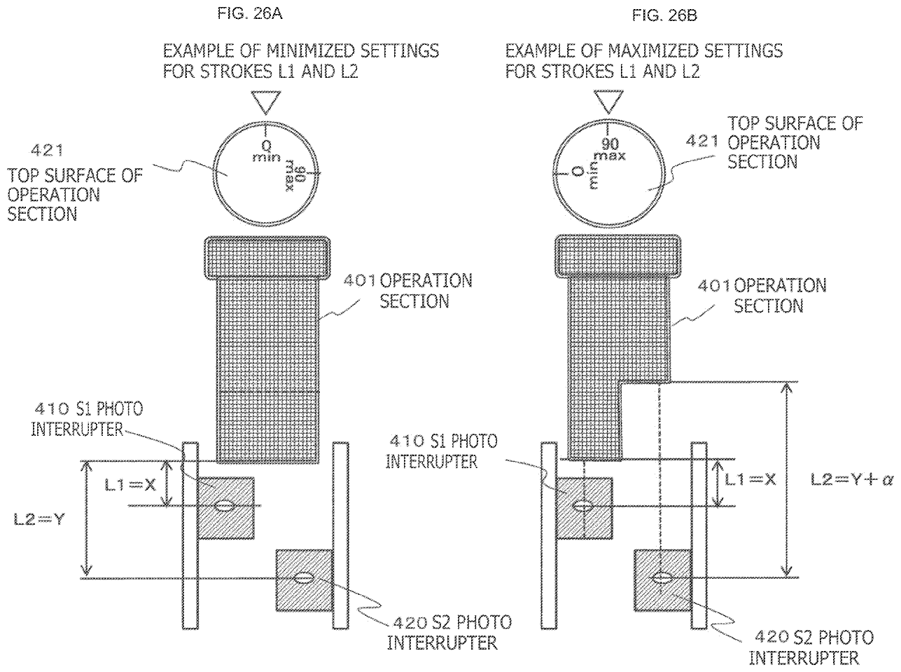

With reference to FIG. 26, a specific example will be described in which the user rotates the operation section 401 to adjust the stroke L.

FIG. 26 illustrates the following two examples:

(1) an example of minimum settings of the strokes L1 and L2, and

(2) an example of the maximum settings of the strokes L1 and L2.

In (1), both strokes L1 and L2 are set to unadjusted minimum strokes. Setting points of 0 (min) and 90 (max) are indicated on the top surface of the operation section 421. The user rotates the setting points to predetermined positions.

(1) indicates a state in which the strokes L1 and L2 are unadjusted, that is, the user has not performed the rotation operation, and the amount of rotation of the operation section 401 is 0. In this case, as depicted in FIG. 26, 0 (min) corresponding to a setting point is located at a predetermined position on the top surface of the operation section 421. The strokes L1 and L2 are as follows.

Stroke L1=X

Stroke L2=Y (1)

On the other hand, FIG. 26(2) illustrates a state in which the stroke L2 has been adjusted and in which the user has performed the rotation operation to rotate the operation section 401 counterclockwise through 90 degrees. The amount of rotation of the operation section 401 is 90. At this time, 90 (max) corresponding to a setting point is located at a predetermined position on the top surface of the operation section 421. The strokes L1 and L2 at the amount of rotation of 90 are as follows.

Stroke L1=X

Stroke L2=Y+α (2)

A comparison of the stroke L1 between (1) and (2) indicates that despite the rotation of the operation section 401, the height of the initial position S0 with respect to the S1 photo interrupter 410 remains unchanged, and thus the stroke L1 remains X. On the other hand, a comparison of the stroke L2 between (1) and (2) indicates that the rotation operation of the user moves the cutout portion 402 formed in the operation section 401, by an amount of rotation of 90 to set, at the upper end of the cutout portion 402, the initial position S0 of the operation section 401 with respect to the S2 photo interrupter 420. Accordingly, the stroke L2 at Y is increased by a stroke a and thus maximized.

Thus, in the present example, the cutout is formed in the operation section 401, and by rotating the operation section 401, the user can adjust the stroke L2. Note that the present example is illustrative and that the stroke L1 and the like may also be adjustable.

Note that the configuration of the cutout portion 402 is not limited to the stepped type described above and can be configured in various manners.

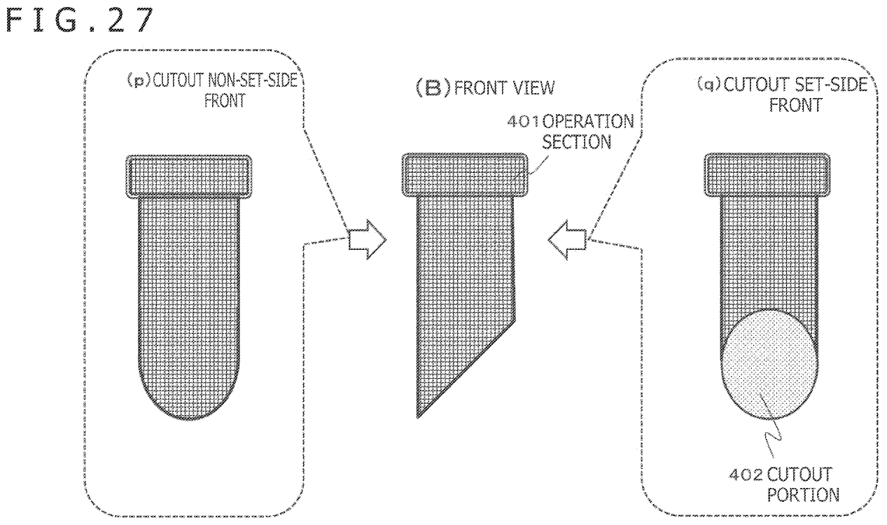

FIG. 27 illustrates a configuration example of the operation section 401 including an inclined cutout portion 402 obtained by oblique slicing.

In the center of FIG. 27, (B) front view of the operation section 401 is depicted. A (p) cutout non-set side front depicted on the left of FIG. 27 is a diagram of the operation section 401 observed from the left of (B) front view. The cutout portion 402 is invisible on this side.

On the other hand, a (q) cutout set side front depicted on the right of FIG. 27 is a diagram of the operation section observed from the right of the (B) front view. On this side, the overall cutout portion 402 in a slice shape can be observed. In this case, the length (height) of a long side of the cutout portion 402 is denoted as a.

The cutout portion can be moved, by the rotation operation of the user, around the rotation axis extending through the operation section 401 in the perpendicular direction. The rotation axis in the present example is an axis extending through the center of a circle corresponding to the shape of the operation section 401 as viewed from the top surface of the operation section 401.

In the present example as well, by rotating the operation section 401, the user can adjust the stroke L.

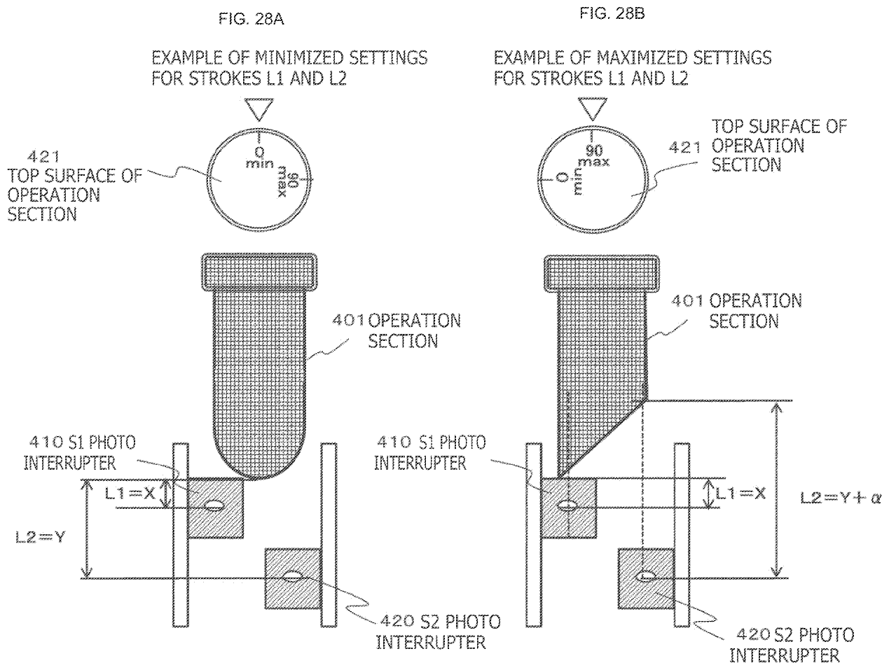

With reference to FIG. 28, a specific example will be described in which the stroke L is adjusted.

FIG. 28 illustrates the following two examples:

(1) an example of minimum settings of the strokes L1 and L2, and

(2) an example of maximum settings of the strokes L1 and L2.

In (1), both strokes L1 and L2 are set to unadjusted minimum strokes. Setting points of 0 (min) and 90 (max) are indicated on the top surface of the operation section 421. The user rotates the setting points to predetermined positions.

(1) indicates a state in which the strokes L1 and L2 are unadjusted, that is, the user has not performed the rotation operation, and the amount of rotation of the operation section 401 is 0. At this point, as depicted in FIG. 28, 0 (min) corresponding to a setting point is located at a predetermined position on the top surface of the operation section 421. The strokes L1 and L2 are as follows.

Stroke L1=X

Stroke L2=Y (1)

On the other hand, FIG. 28(2) illustrates a state in which the user has performed the rotation operation to rotate the operation section 401 counterclockwise through 90 degrees. The amount of rotation of the operation section 401 is 90. At this time, 90 (max) corresponding to a setting point is located at a predetermined position on the top surface of the operation section 421. The strokes L1 and L2 are as follows.

Stroke L1=X

Stroke L2=Y+α (2)

A comparison of the stroke L1 between (1) and (2) indicates that despite the rotation of the operation section 401, the height of the initial position S0 with respect to the S1 photo interrupter 410 remains unchanged, and thus the stroke L1 remains X. On the other hand, a comparison of the stroke L2 between (1) and (2) indicates that the rotation operation of the user moves the cutout portion 402 formed in the operation section 401 to set, at the upper end of the cutout portion 402, the initial position S0 with respect to the S2 photo interrupter 420. Accordingly, the stroke L2 at Y is increased by a stroke a and thus maximized.

This configuration enables the stroke L to be varied smoothly according to the amount of rotation of the operation section 401.

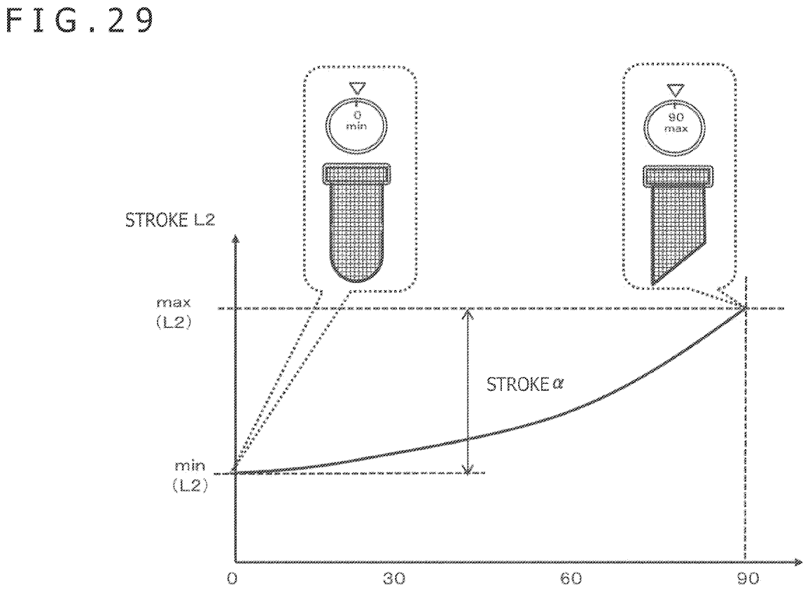

A graph depicted in FIG. 29 indicates a correspondence relation between the amount of rotation of the operation section 401 and the stroke L2.

As is understood from the graph, the stroke L can smoothly be varied according to the amount of rotation of the operation section 401 by the user. Note that the present example is illustrative and that the stroke L1 and the like may also be adjustable.

### 9. Other Modified Examples

In the above-described examples, the configuration has been described in which control is performed to block the output light between the light emission section 24 and the light reception section 25 by the operation section 15 to start various types of processing such as the AF processing and the image capturing processing.

The output light emitted from the light emission section 24 and blocked by the operation section 15 is not limited to visible light and may be infrared light. Alternatively, laser light may be used.

Further, the position detection section 21 may be configured to use, for example, ultrasonic waves, sound waves, electric waves, or the like, as well as light. However, in any case, the position detection section 21 is preferably configured to use signals with high directionality.

### 10. Applied Examples

The technique according to the present disclosure can be applied to various products. For example, the technique according to the present disclosure can be applied as switches for various types of equipment used in an operating room system, for example, a release switch for an endoscope.

Additionally, the configuration of the present disclosure can be caused to execute various types of processing (S1- to Sn-on corresponding processing) according to depression of the operation section 15 of the release switch. Thus, for example, processing as described below can easily be switched by the depression of the operation section 15.

(a) Switching of Electronic Zoom

The present example is configured to be able to execute the autofocus processing as the S2-on corresponding processing and manual focus processing as the S3-on corresponding processing, and then by performing the depression operation, the user can easily switch a focus function.

(b) Switching Processing for the Image Capturing Mode

Normally, the endoscope constantly captures moving images and captures still images as necessary. For example, the present example is configured to be able to execute moving image capturing processing as the S2-on corresponding processing and still image capturing processing as the S3-on corresponding processing, and then by performing the depression operation, the user can easily switch image capturing function.

The present example can also be configured such that processing as described below can be executed as the S3-on corresponding processing.

(c) White Balance Processing

For example, by pushing the operation section 15 further from the position of the S2 corresponding light emission section 28 and the S2 corresponding light reception section 29, the user can easily execute white balance correction processing.

(d) Enhance Level Change Processing

For example, by pushing the operation section 15 further from the position of the S2 corresponding light emission section 28 and the S2 corresponding light reception section 29, the user can easily execute enhance level change processing.

(e) Processing for Rotating a Video Through 180° for Output

For example, by pushing the operation section 15 further from the position of the S2 corresponding light emission section 28 and the S2 corresponding light reception section 29, the user can easily switch a video displayed on the screen to the video rotated through 180°.

(f) Screen Freeze Processing

For example, by pushing the operation section 15 further from the position of the S2 corresponding light emission section 28 and the S2 corresponding light reception section 29, the user can easily execute freeze processing on an image displayed on the screen.

(g) Remote Control Processing on a Video Printer

For example, by pushing the operation section 15 further from the position of the S2 corresponding light emission section 28 and the S2 corresponding light reception section 29, the user can remotely control a video printer to execute print-out processing on an image displayed on the screen.

Note that the processing described above is only illustrative and is not intended to limit the various types of processing. Additionally, the S1-, S2-, and S3-on corresponding processing can be combined in various manners other than those illustrated above.

Additionally, unlike methods for detecting the position of the operation section 15 with respect to the detection position on the basis of contact of a metal plate as in the related art, the detection method using the photo interrupters as in the examples of the present disclosure involves no metallic wear caused by high-pressure cleaning and can thus be said to correspond to a structure suitable for autoclave sterilization treatment of an endoscope.

A description will be given of a configuration example of an operating room system to which the technique according to the present disclosure can be applied.

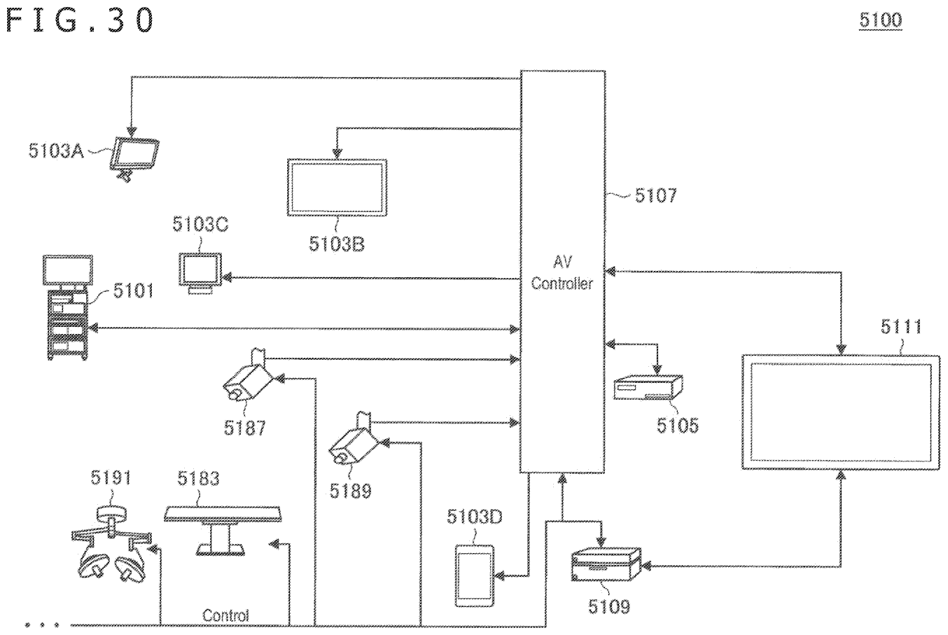

FIG. 30 is a view schematically depicting a general configuration of an operating room system 5100 to which the technology according to an embodiment of the present disclosure can be applied. Referring to FIG. 30, the operating room system 5100 is configured such that a group of apparatus installed in an operating room are connected for cooperation with each other through an audiovisual (AV) controller 5107 and an operating room controlling apparatus 5109.

In the operating room, various apparatus may be installed. In FIG. 30, as an example, various apparatus group 5101 for endoscopic surgery, a ceiling camera 5187, a surgery field camera 5189, a plurality of display apparatus 5103A to 5103D, a recorder 5105, a patient bed 5183 and an illumination 5191 are depicted. The ceiling camera 5187 is provided on the ceiling of an operating room and images the hands of a surgeon. The surgery field camera 5189 is provided on the ceiling of the operating room and images a state of the entire operating room.

Among the apparatus mentioned, the apparatus group 5101 belongs to an endoscopic surgery system 5113 hereinafter described and include an endoscope, a display apparatus which displays an image picked up by the endoscope and so forth. Various apparatus belonging to the endoscopic surgery system 5113 are referred to also as medical equipment. Meanwhile, the display apparatus 5103A to 5103D, the recorder 5105, the patient bed 5183 and the illumination 5191 are apparatus which are equipped, for example, in the operating room separately from the endoscopic surgery system 5113. The apparatus which do not belong to the endoscopic surgery system 5113 are referred to also as non-medical equipment. The audiovisual controller 5107 and/or the operating room controlling apparatus 5109 cooperatively control operation of the medical equipment and the non-medical equipment with each other.

The audiovisual controller 5107 integrally controls processes of the medical equipment and the non-medical equipment relating to image display. Specifically, each of the apparatus group 5101, the ceiling camera 5187 and the surgery field camera 5189 from among the apparatus provided in the operating room system 5100 may be an apparatus having a function of sending information to be displayed during surgery (such information is hereinafter referred to as display information, and the apparatus mentioned is hereinafter referred to as apparatus of a sending source). Meanwhile, each of the display apparatus 5103A to 5103D may be an apparatus to which display information is outputted (the apparatus is hereinafter referred to also as apparatus of an output destination). Further, the recorder 5105 may be an apparatus which serves as both of an apparatus of a sending source and an apparatus of an output destination. The audiovisual controller 5107 has a function of controlling operation of an apparatus of a sending source and an apparatus of an output destination to acquire display information from the apparatus of a sending source and transmit the display information to the apparatus of an output destination so as to be displayed or recorded. It is to be noted that the display information includes various images picked up during surgery, various kinds of information relating to the surgery (for example, physical information of a patient, inspection results in the past or information regarding a surgical procedure) and so forth.

Specifically, to the audiovisual controller 5107, information relating to an image of a surgical region in a body cavity of a patient imaged by the endoscope may be transmitted as the display information from the apparatus group 5101. Further, from the ceiling camera 5187, information relating to an image of the hands of the surgeon picked up by the ceiling camera 5187 may be transmitted as display information. Further, from the surgery field camera 5189, information relating to an image picked up by the surgery field camera 5189 and illustrating a state of the entire operating room may be transmitted as display information. It is to be noted that, if a different apparatus having an image pickup function exists in the operating room system 5100, then the audiovisual controller 5107 may acquire information relating to an image picked up by the different apparatus as display information also from the different apparatus.

Alternatively, for example, in the recorder 5105, information relating to such images as mentioned above picked up in the past is recorded by the audiovisual controller 5107. The audiovisual controller 5107 can acquire, as display information, information relating to the images picked up in the past from the recorder 5105. It is to be noted that also various pieces of information relating to surgery may be recorded in advance in the recorder 5105.

The audiovisual controller 5107 controls at least one of the display apparatus 5103A to 5103D, which are apparatus of an output destination, to display acquired display information (namely, images picked up during surgery or various pieces of information relating to the surgery). In the example depicted, the display apparatus 5103A is a display apparatus installed so as to be suspended from the ceiling of the operating room; the display apparatus 5103B is a display apparatus installed on a wall face of the operating room; the display apparatus 5103C is a display apparatus installed on a desk in the operating room; and the display apparatus 5103D is a mobile apparatus (for example, a tablet personal computer (PC)) having a display function.

Further, though not depicted in FIG. 30, the operating room system 5100 may include an apparatus outside the operating room. The apparatus outside the operating room may be, for example, a server connected to a network constructed inside and outside the hospital, a PC used by medical staff, a projector installed in a meeting room of the hospital or the like. Where such an external apparatus is located outside the hospital, also it is possible for the audiovisual controller 5107 to cause display information to be displayed on a display apparatus of a different hospital through a teleconferencing system or the like to perform telemedicine.

The operating room controlling apparatus 5109 integrally controls processes other than processes relating to image display on the non-medical equipment. For example, the operating room controlling apparatus 5109 controls driving of the patient bed 5183, the ceiling camera 5187, the surgery field camera 5189 and the illumination 5191.

In the operating room system 5100, a centralized operation panel 5111 is provided such that it is possible to issue an instruction regarding image display to the audiovisual controller 5107 or issue an instruction regarding operation of the non-medical equipment to the operating room controlling apparatus 5109 through the centralized operation panel 5111. The centralized operation panel 5111 is configured by providing a touch panel on a display face of a display apparatus.

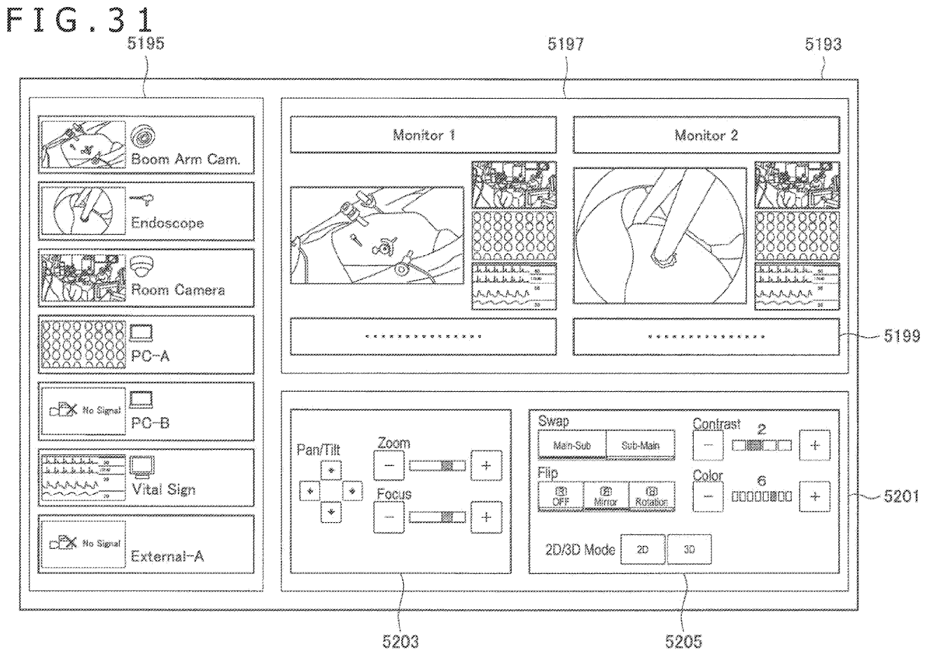

FIG. 31 is a view depicting an example of display of an operation screen image on the centralized operation panel 5111. In FIG. 31, as an example, an operation screen image is depicted which corresponds to a case in which two display apparatus are provided as apparatus of an output destination in the operating room system 5100. Referring to FIG. 31, the operation screen image 5193 includes a sending source selection region 5195, a preview region 5197 and a control region 5201.

In the sending source selection region 5195, the sending source apparatus provided in the operating room system 5100 and thumbnail screen images representative of display information the sending source apparatus have are displayed in an associated manner with each other. A user can select display information to be displayed on the display apparatus from any of the sending source apparatus displayed in the sending source selection region 5195.

In the preview region 5197, a preview of screen images displayed on two display apparatus (Monitor 1 and Monitor 2) which are apparatus of an output destination is displayed. In the example depicted, four images are displayed by picture in picture (PinP) display in regard to one display apparatus. The four images correspond to display information sent from the sending source apparatus selected in the sending source selection region 5195. One of the four images is displayed in a comparatively large size as a main image while the remaining three images are displayed in a comparatively small size as sub images. The user can exchange between the main image and the sub images by suitably selecting one of the images from among the four images displayed in the region. Further, a status displaying region 5199 is provided below the region in which the four images are displayed, and a status relating to surgery (for example, elapsed time of the surgery, physical information of the patient and so forth) may be displayed suitably in the status displaying region 5199.

A sending source operation region 5203 and an output destination operation region 5205 are provided in the control region 5201. In the sending source operation region 5203, a graphical user interface (GUI) part for performing an operation for an apparatus of a sending source is displayed. In the output destination operation region 5205, a GUI part for performing an operation for an apparatus of an output destination is displayed. In the example depicted, GUI parts for performing various operations for a camera (panning, tilting and zooming) in an apparatus of a sending source having an image pickup function are provided in the sending source operation region 5203. The user can control operation of the camera of an apparatus of a sending source by suitably selecting any of the GUI parts. It is to be noted that, though not depicted, where the apparatus of a sending source selected in the sending source selection region 5195 is a recorder (namely, where an image recorded in the recorder in the past is displayed in the preview region 5197), GUI parts for performing such operations as reproduction of the image, stopping of reproduction, rewinding, fast-feeding and so forth may be provided in the sending source operation region 5203.

Further, in the output destination operation region 5205, GUI parts for performing various operations for display on a display apparatus which is an apparatus of an output destination (swap, flip, color adjustment, contrast adjustment and switching between two dimensional (2D) display and three dimensional (3D) display) are provided. The user can operate the display of the display apparatus by suitably selecting any of the GUI parts.

It is to be noted that the operation screen image to be displayed on the centralized operation panel 5111 is not limited to the depicted example, and the user may be able to perform operation inputting to each apparatus which can be controlled by the audiovisual controller 5107 and the operating room controlling apparatus 5109 provided in the operating room system 5100 through the centralized operation panel 5111.

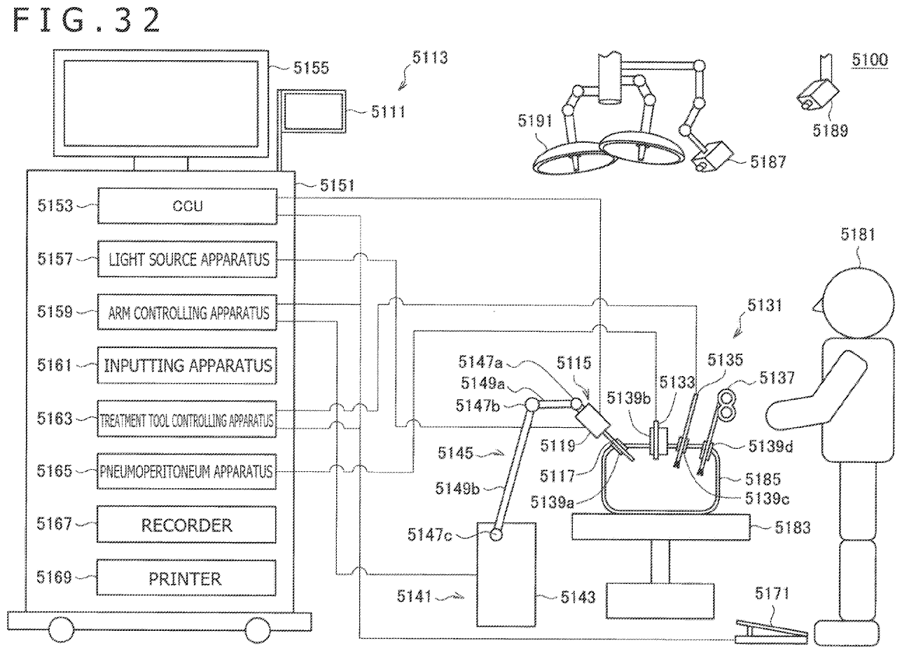

FIG. 32 is a view illustrating an example of a state of surgery to which the operating room system described above is applied. The ceiling camera 5187 and the surgery field camera 5189 are provided on the ceiling of the operating room such that it can image the hands of a surgeon (medical doctor) 5181 who performs treatment for an affected area of a patient 5185 on the patient bed 5183 and the entire operating room. The ceiling camera 5187 and the surgery field camera 5189 may include a magnification adjustment function, a focal distance adjustment function, an imaging direction adjustment function and so forth. The illumination 5191 is provided on the ceiling of the operating room and irradiates at least upon the hands of the surgeon 5181. The illumination 5191 may be configured such that the irradiation light amount, the wavelength (color) of the irradiation light, the irradiation direction of the light and so forth can be adjusted suitably.

The endoscopic surgery system 5113, the patient bed 5183, the ceiling camera 5187, the surgery field camera 5189 and the illumination 5191 are connected for cooperation with each other through the audiovisual controller 5107 and the operating room controlling apparatus 5109 (not depicted in FIG. 32) as depicted in FIG. 30. The centralized operation panel 5111 is provided in the operating room, and the user can suitably operate the apparatus existing in the operating room through the centralized operation panel 5111 as described hereinabove.

In the following, a configuration of the endoscopic surgery system 5113 is described in detail. As depicted, the endoscopic surgery system 5113 includes an endoscope 5115, other surgical tools 5131, a supporting arm apparatus 5141 which supports the endoscope 5115 thereon, and a cart 5151 on which various apparatus for endoscopic surgery are mounted.

In endoscopic surgery, in place of incision of the abdominal wall to perform laparotomy, a plurality of tubular aperture devices called trocars 5139a to 5139d are used to puncture the abdominal wall. Then, a lens barrel 5117 of the endoscope 5115 and the other surgical tools 5131 are inserted into body cavity of the patient 5185 through the trocars 5139a to 5139d. In the example depicted, as the other surgical tools 5131, a pneumoperitoneum tube 5133, an energy device 5135 and forceps 5137 are inserted into body cavity of the patient 5185. Further, the energy device 5135 is a treatment tool for performing incision and peeling of a tissue, sealing of a blood vessel or the like by high frequency current or ultrasonic vibration. However, the surgical tools 5131 depicted are mere examples at all, and as the surgical tools 5131, various surgical tools which are generally used in endoscopic surgery such as, for example, tweezers or a retractor may be used.

An image of a surgical region in a body cavity of the patient 5185 picked up by the endoscope 5115 is displayed on a display apparatus 5155. The surgeon 5181 would use the energy device 5135 or the forceps 5137 while watching the image of the surgical region displayed on the display apparatus 5155 on the real time basis to perform such treatment as, for example, resection of an affected area. It is to be noted that, though not depicted, the pneumoperitoneum tube 5133, the energy device 5135, and the forceps 5137 are supported by the surgeon 5181, an assistant or the like during surgery.

### (Supporting Arm Apparatus)

The supporting arm apparatus 5141 includes an arm unit 5145 extending from a base unit 5143. In the example depicted, the arm unit 5145 includes joint portions 5147a, 5147b and 5147c and links 5149a and 5149b and is driven under the control of an arm controlling apparatus 5159. The endoscope 5115 is supported by the arm unit 5145 such that the position and the posture of the endoscope 5115 are controlled. Consequently, stable fixation in position of the endoscope 5115 can be implemented.

### (Endoscope)

The endoscope 5115 includes the lens barrel 5117 which has a region of a predetermined length from a distal end thereof to be inserted into a body cavity of the patient 5185, and a camera head 5119 connected to a proximal end of the lens barrel 5117. In the example depicted, the endoscope 5115 is depicted as a rigid endoscope having the lens barrel 5117 of the hard type. However, the endoscope 5115 may otherwise be configured as a flexible endoscope having the lens barrel 5117 of the flexible type.

The lens barrel 5117 has, at a distal end thereof, an opening in which an objective lens is fitted. A light source apparatus 5157 is connected to the endoscope 5115 such that light generated by the light source apparatus 5157 is introduced to a distal end of the lens barrel 5117 by a light guide extending in the inside of the lens barrel 5117 and is applied toward an observation target in a body cavity of the patient 5185 through the objective lens. It is to be noted that the endoscope 5115 may be a forward-viewing endoscope or may be an oblique-viewing endoscope or a side-viewing endoscope.

An optical system and an image pickup element are provided in the inside of the camera head 5119 such that reflected light (observation light) from an observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 5153. It is to be noted that the camera head 5119 has a function incorporated therein for suitably driving the optical system of the camera head 5119 to adjust the magnification and the focal distance.

It is to be noted that, in order to establish compatibility with, for example, a stereoscopic vision (3D display), a plurality of image pickup elements may be provided on the camera head 5119. In this case, a plurality of relay optical systems are provided in the inside of the lens barrel 5117 in order to guide observation light to the plurality of respective image pickup elements.

### (Various Apparatus Incorporated in Cart)

The CCU 5153 includes a central processing unit (CPU), a graphics processing unit (GPU) or the like and integrally controls operation of the endoscope 5115 and the display apparatus 5155. Specifically, the CCU 5153 performs, for an image signal received from the camera head 5119, various image processes for displaying an image based on the image signal such as, for example, a development process (demosaic process). The CCU 5153 provides the image signal for which the image processes have been performed to the display apparatus 5155. Further, the audiovisual controller 5107 depicted in FIG. 30 is connected to the CCU 5153. The CCU 5153 provides the image signal for which the image processes have been performed also to the audiovisual controller 5107. Further, the CCU 5153 transmits a control signal to the camera head 5119 to control driving of the camera head 5119. The control signal may include information relating to an image pickup condition such as a magnification or a focal distance. The information relating to an image pickup condition may be inputted through the inputting apparatus 5161 or may be inputted through the centralized operation panel 5111 described hereinabove.

The display apparatus 5155 displays an image based on an image signal for which the image processes have been performed by the CCU 5153 under the control of the CCU 5153. If the endoscope 5115 is ready for imaging of a high resolution such as 4K (horizontal pixel number 3840×vertical pixel number 2160), 8K (horizontal pixel number 7680×vertical pixel number 4320) or the like and/or ready for 3D display, then a display apparatus by which corresponding display of the high resolution and/or 3D display are possible may be used as the display apparatus 5155. Where the apparatus is ready for imaging of a high resolution such as 4K or 8K, if the display apparatus used as the display apparatus 5155 has a size of equal to or not less than 55 inches, then a more immersive experience can be obtained. Further, a plurality of display apparatus 5155 having different resolutions and/or different sizes may be provided in accordance with purposes.

The light source apparatus 5157 includes a light source such as, for example, a light emitting diode (LED) and supplies irradiation light for imaging of a surgical region to the endoscope 5115.

The arm controlling apparatus 5159 includes a processor such as, for example, a CPU and operates in accordance with a predetermined program to control driving of the arm unit 5145 of the supporting arm apparatus 5141 in accordance with a predetermined controlling method.

An inputting apparatus 5161 is an input interface for the endoscopic surgery system 5113. A user can perform inputting of various kinds of information or instruction inputting to the endoscopic surgery system 5113 through the inputting apparatus 5161. For example, the user would input various kinds of information relating to surgery such as physical information of a patient, information regarding a surgical procedure of the surgery and so forth through the inputting apparatus 5161. Further, the user would input, for example, an instruction to drive the arm unit 5145, an instruction to change an image pickup condition (type of irradiation light, magnification, focal distance or the like) by the endoscope 5115, an instruction to drive the energy device 5135 or a like through the inputting apparatus 5161.

The type of the inputting apparatus 5161 is not limited and may be that of any one of various known inputting apparatus. As the inputting apparatus 5161, for example, a mouse, a keyboard, a touch panel, a switch, a foot switch 5171 and/or a lever or the like may be applied. Where a touch panel is used as the inputting apparatus 5161, it may be provided on the display face of the display apparatus 5155.

The inputting apparatus 5161 is otherwise a device to be mounted on a user such as, for example, a glasses type wearable device or a head mounted display (HMD), and various kinds of inputting are performed in response to a gesture or a line of sight of the user detected by any of the devices mentioned. Further, the inputting apparatus 5161 includes a camera which can detect a motion of a user, and various kinds of inputting are performed in response to a gesture or a line of sight of a user detected from a video picked up by the camera. Further, the inputting apparatus 5161 includes a microphone which can collect the voice of a user, and various kinds of inputting are performed by voice through the microphone. By configuring the inputting apparatus 5161 such that various kinds of information can be inputted in a contactless fashion in this manner, especially a user who belongs to a clean area (for example, the surgeon 5181) can operate an apparatus belonging to an unclean area in a contactless fashion. Further, since the user can operate an apparatus without releasing a possessed surgical tool from its hand, the convenience to the user is improved.

A treatment tool controlling apparatus 5163 controls driving of the energy device 5135 for cautery or incision of a tissue, sealing of a blood vessel or the like. A pneumoperitoneum apparatus 5165 feeds gas into a body cavity of the patient 5185 through the pneumoperitoneum tube 5133 to inflate the body cavity in order to secure the field of view of the endoscope 5115 and secure the working space for the surgeon. A recorder 5167 is an apparatus capable of recording various kinds of information relating to surgery. A printer 5169 is an apparatus capable of printing various kinds of information relating to surgery in various forms such as a text, an image or a graph.

In the following, especially a characteristic configuration of the endoscopic surgery system 5113 is described in more detail.

### (Supporting Arm Apparatus)

The supporting arm apparatus 5141 includes the base unit 5143 serving as a base, and the arm unit 5145 extending from the base unit 5143. In the example depicted, the arm unit 5145 includes the plurality of joint portions 5147a, 5147b and 5147c and the plurality of links 5149a and 5149b connected to each other by the joint portion 5147b. In FIG. 32, for simplified illustration, the configuration of the arm unit 5145 is depicted in a simplified form. Actually, the shape, number and arrangement of the joint portions 5147a to 5147c and the links 5149a and 5149b and the direction and so forth of axes of rotation of the joint portions 5147a to 5147c can be set suitably such that the arm unit 5145 has a desired degree of freedom. For example, the arm unit 5145 may preferably be included such that it has a degree of freedom equal to or not less than 6 degrees of freedom. This makes it possible to move the endoscope 5115 freely within the movable range of the arm unit 5145. Consequently, it becomes possible to insert the lens barrel 5117 of the endoscope 5115 from a desired direction into a body cavity of the patient 5185.

An actuator is provided in the joint portions 5147a to 5147c, and the joint portions 5147a to 5147c include such that they are rotatable around predetermined axes of rotation thereof by driving of the actuator. The driving of the actuator is controlled by the arm controlling apparatus 5159 to control the rotational angle of each of the joint portions 5147a to 5147c thereby to control driving of the arm unit 5145. Consequently, control of the position and the posture of the endoscope 5115 can be implemented. Thereupon, the arm controlling apparatus 5159 can control driving of the arm unit 5145 by various known controlling methods such as force control or position control.

For example, if the surgeon 5181 suitably performs operation inputting through the inputting apparatus 5161 (including the foot switch 5171), then driving of the arm unit 5145 may be controlled suitably by the arm controlling apparatus 5159 in response to the operation input to control the position and the posture of the endoscope 5115. After the endoscope 5115 at the distal end of the arm unit 5145 is moved from an arbitrary position to a different arbitrary position by the control just described, the endoscope 5115 can be supported fixedly at the position after the movement. It is to be noted that the arm unit 5145 may be operated in a master-slave fashion. In this case, the arm unit 5145 may be remotely controlled by the user through the inputting apparatus 5161 which is placed at a place remote from the operating room.

Further, where force control is applied, the arm controlling apparatus 5159 may perform power-assisted control to drive the actuators of the joint portions 5147a to 5147c such that the arm unit 5145 may receive external force by the user and move smoothly following the external force. This makes it possible to move the arm unit 5145 with comparatively weak force when the user directly touches with and moves the arm unit 5145. Accordingly, it becomes possible for the user to move the endoscope 5115 more intuitively by a simpler and easier operation, and the convenience to the user can be improved.

Here, generally in endoscopic surgery, the endoscope 5115 is supported by a medical doctor called scopist. In contrast, where the supporting arm apparatus 5141 is used, the position of the endoscope 5115 can be fixed with a higher degree of certainty without hands, and therefore, an image of a surgical region can be obtained stably and surgery can be performed smoothly.

It is to be noted that the arm controlling apparatus 5159 may not necessarily be provided on the cart 5151. Further, the arm controlling apparatus 5159 may not necessarily be a single apparatus. For example, the arm controlling apparatus 5159 may be provided in each of the joint portions 5147a to 5147c of the arm unit 5145 of the supporting arm apparatus 5141 such that the plurality of arm controlling apparatus 5159 cooperate with each other to implement driving control of the arm unit 5145.

### (Light Source Apparatus)

The light source apparatus 5157 supplies irradiation light upon imaging of a surgical region to the endoscope 5115. The light source apparatus 5157 includes a white light source which includes, for example, an LED, a laser light source or a combination of them. In this case, where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 5157. Further, in this case, if laser beams from the RGB laser light sources are applied time-divisionally on an observation target and driving of the image pickup elements of the camera head 5119 is controlled in synchronism with the irradiation timings, then images individually corresponding to the R, G and B colors can be picked up time-divisionally. According to the method just described, a color image can be obtained even if a color filter is not provided for the image pickup element.

Further, driving of the light source apparatus 5157 may be controlled such that the intensity of light to be outputted is changed for each predetermined time. By controlling driving of the image pickup element of the camera head 5119 in synchronism with the timing of the change of the intensity of light to acquire images time-divisionally and synthesizing the images, an image of a high dynamic range free from underexposed blocked up shadows and overexposed highlights can be created.

Further, the light source apparatus 5157 may be configured to supply light of a predetermined wavelength band ready for special light observation. In special light observation, for example, by utilizing the wavelength dependency of absorption of light of a body tissue, narrow band light observation (narrow band imaging) of imaging a predetermined tissue such as a blood vessel of a superficial portion of the mucous membrane or the like in a high contrast is performed by applying light of a narrower wavelength band in comparison with irradiation light upon ordinary observation (namely, white light). Alternatively, in special light observation, fluorescent observation for obtaining an image from fluorescent light generated by irradiation of excitation light may also be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 5157 can be configured to supply such narrow-band light and/or excitation light suitable for special light observation as described above.

### (Camera Head and CCU)

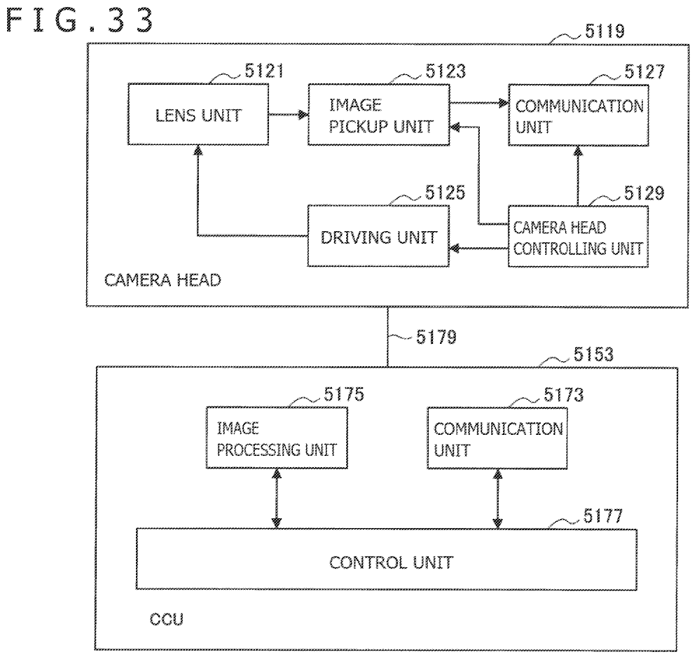

Functions of the camera head 5119 of the endoscope 5115 and the CCU 5153 are described in more detail with reference to FIG. 33. FIG. 33 is a block diagram depicting an example of a functional configuration of the camera head 5119 and the CCU 5153 depicted in FIG. 32.

Referring to FIG. 33, the camera head 5119 has, as functions thereof, a lens unit 5121, an image pickup unit 5123, a driving unit 5125, a communication unit 5127 and a camera head controlling unit 5129. Further, the CCU 5153 has, as functions thereof, a communication unit 5173, an image processing unit 5175 and a control unit 5177. The camera head 5119 and the CCU 5153 are connected to be bidirectionally communicable to each other by a transmission cable 5179.

First, a functional configuration of the camera head 5119 is described. The lens unit 5121 is an optical system provided at a connecting location of the camera head 5119 to the lens barrel 5117. Observation light taken in from a distal end of the lens barrel 5117 is introduced into the camera head 5119 and enters the lens unit 5121. The lens unit 5121 includes a combination of a plurality of lenses including a zoom lens and a focusing lens. The lens unit 5121 has optical properties adjusted such that the observation light is condensed on a light receiving face of the image pickup element of the image pickup unit 5123. Further, the zoom lens and the focusing lens include such that the positions thereof on their optical axis are movable for adjustment of the magnification and the focal point of a picked up image.

The image pickup unit 5123 includes an image pickup element and disposed at a succeeding stage to the lens unit 5121. Observation light having passed through the lens unit 5121 is condensed on the light receiving face of the image pickup element, and an image signal corresponding to the observation image is generated by photoelectric conversion. The image signal generated by the image pickup unit 5123 is provided to the communication unit 5127.

As the image pickup element which is included by the image pickup unit 5123, an image sensor, for example, of the complementary metal oxide semiconductor (CMOS) type is used which has a Bayer array and is capable of picking up an image in color. It is to be noted that, as the image pickup element, an image pickup element may be used which is ready, for example, for imaging of an image of a high resolution equal to or not less than 4K. If an image of a surgical region is obtained in a high resolution, then the surgeon 5181 can comprehend a state of the surgical region in enhanced details and can proceed with the surgery more smoothly.

Further, the image pickup element which is included by the image pickup unit 5123 is configured such that it has a pair of image pickup elements for acquiring image signals for the right eye and the left eye compatible with 3D display. Where 3D display is applied, the surgeon 5181 can comprehend the depth of a living body tissue in the surgical region with a higher degree of accuracy. It is to be noted that, if the image pickup unit 5123 is configured as that of the multi-plate type, then a plurality of systems of lens units 5121 are provided corresponding to the individual image pickup elements of the image pickup unit 5123.

The image pickup unit 5123 may not necessarily be provided on the camera head 5119. For example, the image pickup unit 5123 may be provided just behind the objective lens in the inside of the lens barrel 5117.

The driving unit 5125 includes an actuator and moves the zoom lens and the focusing lens of the lens unit 5121 by a predetermined distance along the optical axis under the control of the camera head controlling unit 5129. Consequently, the magnification and the focal point of a picked up image by the image pickup unit 5123 can be adjusted suitably.

The communication unit 5127 includes a communication apparatus for transmitting and receiving various kinds of information to and from the CCU 5153. The communication unit 5127 transmits an image signal acquired from the image pickup unit 5123 as RAW data to the CCU 5153 through the transmission cable 5179. Thereupon, in order to display a picked up image of a surgical region in low latency, preferably the image signal is transmitted by optical communication. This is because, since, upon surgery, the surgeon 5181 performs surgery while observing the state of an affected area through a picked up image, in order to achieve surgery with a higher degree of safety and certainty, it is demanded for a moving image of the surgical region to be displayed on the real time basis as far as possible. Where optical communication is applied, a photoelectric conversion module for converting an electric signal into an optical signal is provided in the communication unit 5127. After the image signal is converted into an optical signal by the photoelectric conversion module, it is transmitted to the CCU 5153 through the transmission cable 5179.

Further, the communication unit 5127 receives a control signal for controlling driving of the camera head 5119 from the CCU 5153. The control signal includes information relating to image pickup conditions such as, for example, information that a frame rate of a picked up image is designated, information that an exposure value upon image picking up is designated and/or information that a magnification and a focal point of a picked up image are designated. The communication unit 5127 provides the received control signal to the camera head controlling unit 5129. It is to be noted that also the control signal from the CCU 5153 may be transmitted by optical communication. In this case, a photoelectric conversion module for converting an optical signal into an electric signal is provided in the communication unit 5127. After the control signal is converted into an electric signal by the photoelectric conversion module, it is provided to the camera head controlling unit 5129.

It is to be noted that the image pickup conditions such as the frame rate, exposure value, magnification or focal point are set automatically by the control unit 5177 of the CCU 5153 on the basis of an acquired image signal. In other words, an auto exposure (AE) function, an auto focus (AF) function and an auto white balance (AWB) function are incorporated in the endoscope 5115.

The camera head controlling unit 5129 controls driving of the camera head 5119 on the basis of a control signal from the CCU 5153 received through the communication unit 5127. For example, the camera head controlling unit 5129 controls driving of the image pickup element of the image pickup unit 5123 on the basis of information that a frame rate of a picked up image is designated and/or information that an exposure value upon image picking up is designated. Further, for example, the camera head controlling unit 5129 controls the driving unit 5125 to suitably move the zoom lens and the focus lens of the lens unit 5121 on the basis of information that a magnification and a focal point of a picked up image are designated. The camera head controlling unit 5129 may include a function for storing information for identifying of the lens barrel 5117 and/or the camera head 5119.

It is to be noted that, by disposing the components such as the lens unit 5121 and the image pickup unit 5123 in a sealed structure having high airtightness and high waterproof, the camera head 5119 can be provided with resistance to an autoclave sterilization process.

Now, a functional configuration of the CCU 5153 is described. The communication unit 5173 includes a communication apparatus for transmitting and receiving various kinds of information to and from the camera head 5119. The communication unit 5173 receives an image signal transmitted thereto from the camera head 5119 through the transmission cable 5179. Thereupon, the image signal may be transmitted preferably by optical communication as described above. In this case, for the compatibility with optical communication, the communication unit 5173 includes a photoelectric conversion module for converting an optical signal into an electric signal. The communication unit 5173 provides the image signal after conversion into an electric signal to the image processing unit 5175.

Further, the communication unit 5173 transmits, to the camera head 5119, a control signal for controlling driving of the camera head 5119. Also the control signal may be transmitted by optical communication.

The image processing unit 5175 performs various image processes for an image signal in the form of RAW data transmitted thereto from the camera head 5119. The image processes include various known signal processes such as, for example, a development process, an image quality improving process (a bandwidth enhancement process, a super-resolution process, a noise reduction (NR) process and/or an image stabilization process) and/or an enlargement process (electronic zooming process). Further, the image processing unit 5175 performs a detection process for an image signal for performing AE, AF and AWB.

The image processing unit 5175 includes a processor such as a CPU or a GPU, and when the processor operates in accordance with a predetermined program, the image processes and the detection process described above can be performed. It is to be noted that, where the image processing unit 5175 includes a plurality of GPUs, the image processing unit 5175 suitably divides information relating to an image signal such that image processes are performed in parallel by the plurality of GPUs.

The control unit 5177 performs various kinds of control relating to image picking up of a surgical region by the endoscope 5115 and display of the picked up image. For example, the control unit 5177 generates a control signal for controlling driving of the camera head 5119. Thereupon, if image pickup conditions are inputted by the user, then the control unit 5177 generates a control signal on the basis of the input by the user. Alternatively, where the endoscope 5115 has an AE function, an AF function and an AWB function incorporated therein, the control unit 5177 suitably calculates an optimum exposure value, focal distance and white balance in response to a result of a detection process by the image processing unit 5175 and generates a control signal.

Further, the control unit 5177 controls the display apparatus 5155 to display an image of a surgical region on the basis of an image signal for which the image processes have been performed by the image processing unit 5175. Thereupon, the control unit 5177 recognizes various objects in the surgical region image using various image recognition technologies. For example, the control unit 5177 can recognize a surgical tool such as forceps, a particular living body region, bleeding, mist when the energy device 5135 is used and so forth by detecting the shape, color and so forth of edges of the objects included in the surgical region image. The control unit 5177 causes, when it controls the display apparatus 5155 to display a surgical region image, various kinds of surgery supporting information to be displayed in an overlapping manner with an image of the surgical region using a result of the recognition. Where surgery supporting information is displayed in an overlapping manner and presented to the surgeon 5181, the surgeon 5181 can proceed with the surgery more safety and certainty.

The transmission cable 5179 which connects the camera head 5119 and the CCU 5153 to each other is an electric signal cable ready for communication of an electric signal, an optical fiber ready for optical communication or a composite cable thereof.

Here, while, in the example depicted in the figure, communication is performed by wired communication using the transmission cable 5179, the communication between the camera head 5119 and the CCU 5153 may be performed otherwise by wireless communication. Where the communication between the camera head 5119 and the CCU 5153 is performed by wireless communication, there is no necessity to lay the transmission cable 5179 in the operating room. Therefore, such a situation that movement of medical staff in the operating room is disturbed by the transmission cable 5179 can be eliminated.

An example of the operating room system 5100 to which the technology according to an embodiment of the present disclosure can be applied has been described above. It is to be noted here that, although a case in which the medical system to which the operating room system 5100 is applied is the endoscopic surgery system 5113 has been described as an example, the configuration of the operating room system 5100 is not limited to that of the example described above. For example, the operating room system 5100 may be applied to a soft endoscopic system for inspection or a microscopic surgery system in place of the endoscopic surgery system 5113.

### 11. Conclusion of Configuration of Present Disclosure

The examples of the present disclosure have been described in detail with reference to the particular examples. However, obviously, those skilled in the art may achieve modification or alteration of the examples without departing from the spirits of the present disclosure. In other words, the present invention has been disclosed in the form of illustration and should not be interpreted in a limited manner. For determination of the spirits of the present disclosure, the claims section should be made allowance for.

Note that the technique disclosed herein can take the following configurations.

(1)

An imaging apparatus including:

an operation section that can move in a predetermined direction from an initial position by a user operation;

a position adjustment section that adjusts, in the predetermined direction, an amount of movement of the operation section from the initial position to a detection position;

a position detection section that detects a position of the operation section with respect to the detection position; and

a control section that controls execution of processing corresponding to the detection position based on a detection result from the position detection section.

(2)

The imaging apparatus according to (1), in which

the position adjustment section adjusts the detection position in the predetermined direction.

(3)

The imaging apparatus according to (1), in which

the position adjustment section adjusts the initial position of the operation section in the predetermined direction.

(4)

The imaging apparatus according to (1), in which

the position detection section includes a light emission section configured to emit output light at the detection position and a light reception section configured to receive the output light emitted by the light emission section, and

the position detection section detects the position of the operation section with respect to the detection position on the basis of whether or not the light reception section has received the output light from the light emission section.

(5)

The imaging apparatus according to any one of (1) to (3), in which

the operation section includes an operation section of a release switch for performing image capturing, by using the imaging apparatus.

(6)

The imaging apparatus according to (4), in which

the position adjustment section moves the light emission section to adjust the amount of movement.

(7)

The imaging apparatus according to (4), in which

the position detection section includes light emission sections respectively provided at plural different positions, and

the position adjustment section includes a light emission section switching section causing at least one of the plural light emission sections to emit light and adjusts the amount of movement by switching of the light emission section performed by the light emission section switching section.

(8)

The imaging apparatus according to (1), in which

the operation section also includes the position adjustment section,

the position adjustment section includes a cutout portion enabling a change in an amount of movement needed for the light reception section to block the output light from the light emission section, and

the amount of movement is enabled to be adjusted by a rotation operation of the operation section.

(9)

The imaging apparatus according to (8), in which

the cutout portion includes a stepped or inclined cutout portion.

(10)

The imaging apparatus according to (1), in which

the control section controls execution of different types of processing corresponding to the respective plural detection positions in the predetermined direction.

The imaging apparatus according to (1), in which,

depending on the detection positions, the control section executes at least one of autofocus (AF) processing, automatic exposure (AE) processing, or image capturing processing.

(12)

The imaging apparatus according to (4), further including:

a contact detection section that detects approach or contact of a hand of a user; and

a light emission control section that executes light emission control of the light emission section according to detection information from the contact detection section.

(13)

The imaging apparatus according to any one of (1) to (12), further including:

a vibration section; and

a vibration control section that executes vibration control of the vibration section, in which

the vibration control section vibrates the vibration section on the basis of the detection result from the position detection section.

(14)

The imaging apparatus according to (10), further including:

a vibration section; and

a vibration control section that executes vibration control of the vibration section, in which

the vibration control section vibrates the vibration section in different vibration modes depending on the plural detection positions.

(15)

A switch including:

an operation section that can move in a predetermined direction from an initial position by a user operation;

a position adjustment section that adjusts, in the predetermined direction, an amount of movement of the operation section from the initial position to a detection position; and

a position detection section that detects a position of the operation section with respect to the detection position.

(16)

The switch according to (15), in which the position adjustment section adjusts the detection position in the predetermined direction.

(17)

The switch according to (15), in which

the position adjustment section adjusts the initial position of the operation section in the predetermined direction.

(18)

The switch according to (15), in which

the position detection section includes a light emission section configured to emit output light at the detection position and a light reception section configured to receive the output light emitted by the light emission section, and

the position detection section detects the position of the operation section with respect to the detection position on the basis of whether or not the light reception section has received the output light from the light emission section.

Further, the sequence of steps of processing described herein can be executed by hardware, software, or a combined configuration of hardware and software. In a case where processing based on software is executed, the processing can be executed by installing a program in which the processing sequence is recorded, into a memory in a computer integrated in dedicated hardware or installing the program on a general-purpose computer that can execute various types of processing. For example, the program can be pre-recorded in a recording medium. Besides installation of the program from the recording medium into the computer, a technique can be used in which the program is received via a network such as a LAN (Local Area Network) or the Internet and installed on a recording medium such as a built-in hard disk.

Note that the various types of processing described herein may be executed in parallel or individually depending on the processing capability of an apparatus executing the processing or as necessary for the apparatus, as well as being executed chronologically in accordance with the description herein. Additionally, the system as used herein is a logical set configuration of plural apparatuses and is not limited to apparatuses having different configurations and located in the same housing.

### INDUSTRIAL APPLICABILITY

As described above, according to the configuration of an example of the present disclosure, a configuration is implemented that can adjust a stroke of an operation section of a switch required to cause predetermined processing to be executed.

Specifically, for example, the configuration includes an operation section enabled to move in a predetermined direction from an initial position by a user operation, a position adjustment section adjusting, in the predetermined direction, an amount of movement of the operation section from the initial position to a detection position, a position detection section detecting a position of the operation section with respect to the detection position, and a control section controlling execution of processing corresponding to the detection position based on a detection result from the position detection section. The present configuration implements a configuration that can adjust the stroke of the operation section of the switch required to cause the predetermined processing to be executed.

### REFERENCE SIGNS LIST

10: Imaging apparatus
11: Lens
12: Release switch
13: User input section
14: Display section
15: Operation section
16: Image sensor
17: Signal processing section
18: Lens system driving section
19: Control section
20: Recording section
21: Position detection section
22: Position adjustment section
23: Processing control section
24: Light emission section
25: Light reception section
26: S1 corresponding light emission section
27: S1 corresponding light reception section
28: S2 corresponding light emission section
29: S2 corresponding light reception section
30: Contact detection section
31: Light emission control section
32: Vibration section
33: Vibration control section
100: Release switch
101: Operation section
110: S1 photo interrupter
111: S1 light emission section
112: S1 light reception section
120: S2 photo interrupter
121: S2 light emission section
122: S2 light reception section
125: S2 photo interrupter integrated gear
131: Adjustment dial
132: Adjustment dial integrated gear
133: Rotation transmitting gear
141: Guide rail
200: Release switch
201: Operation section
210: S1 photo interrupter
211: S1 light emission section
212: S1 light reception section
220: S2 photo interrupter
221: S2 light emission section
222: S2 light reception section
231: S2 light emission section switching section
233: S1 light emission section switching section
240: S2 & S3 photo interrupter
241: S2 light emission section
242: S2 light reception section
243: S3 light emission section
244: S3 light reception section
251: S2 light emission section switching section
252: S3 light emission section switching section
260: S1 & S3 photo interrupter
261: S1 light emission section
262: S1 light reception section
263: S3 light emission section
264: S3 light reception section
270: S2 photo interrupter
271: S2 light emission section
272: S2 light reception section
280: Proximity sensor (or contact sensor)
281: Power supply
285: Proximity sensor (or contact sensor)
290: Vibrator
295: Current control section
296: Coil section
297: Magnet section
298: Magnet section
301: Operation section support section
320: Spring support section
342: Spring support section integrated gear
321: Spring
351: Adjustment dial
352: Adjustment dial integrated gear
353: Rotation transmitting gear
400: Release switch
401: Operation section
410: S1 photo interrupter
411: S1 light emission section
412: S1 light reception section
420: S2 photo interrupter
421: S2 light emission section
422: S2 light reception section

1. An imaging apparatus comprising:
an operation section that can move in a predetermined direction from an initial position by a user operation;
a position adjustment section that adjusts, in the predetermined direction, an amount of movement of the operation section from the initial position to a detection position;
a position detection section that detects a position of the operation section with respect to the detection position; and
a control section that controls execution of processing corresponding to the detection position based on a detection result from the position detection section.

2. The imaging apparatus according to claim 1, wherein
the position adjustment section adjusts the detection position in the predetermined direction.

3. The imaging apparatus according to claim 1, wherein
the position adjustment section adjusts the initial position of the operation section in the predetermined direction.

4. The imaging apparatus according to claim 1, wherein
the position detection section includes a light emission section configured to emit output light at the detection position and a light reception section configured to receive the output light emitted by the light emission section, and
the position detection section detects the position of the operation section with respect to the detection position on a basis of whether or not the light reception section has received the output light from the light emission section.

5. The imaging apparatus according to claim 1, wherein
the operation section includes an operation section of a release switch for performing image capturing, by using the imaging apparatus.

6. The imaging apparatus according to claim 4, wherein
the position adjustment section moves the light emission section to adjust the amount of movement.

7. The imaging apparatus according to claim 4, wherein
the position detection section includes light emission sections respectively provided at plural different positions, and
the position adjustment section includes a light emission section switching section causing at least one of the plural light emission sections to emit light and adjusts the amount of movement by switching of the light emission section performed by the light emission section switching section.

8. The imaging apparatus according to claim 1, wherein
the operation section also includes the position adjustment section,
the position adjustment section includes a cutout portion enabling a change in an amount of movement needed for the light reception section to block the output light from the light emission section, and
the amount of movement is enabled to be adjusted by a rotation operation of the operation section.

9. The imaging apparatus according to claim 8, wherein
the cutout portion includes a stepped or inclined cutout portion.

10. The imaging apparatus according to claim 1, wherein
the control section controls execution of different types of processing corresponding to the respective plural detection positions in the predetermined direction.

11. The imaging apparatus according to claim 1, wherein,
depending on the detection positions, the control section executes at least one of autofocus (AF) processing, automatic exposure (AE) processing, or image capturing processing.

12. The imaging apparatus according to claim 4, further comprising:
a contact detection section that detects approach or contact of a hand of a user; and
a light emission control section that executes light emission control of the light emission section according to detection information from the contact detection section.

13. The imaging apparatus according to claim 1, further comprising:
a vibration section; and
a vibration control section that executes vibration control of the vibration section, wherein
the vibration control section vibrates the vibration section on a basis of the detection result from the position detection section.

14. The imaging apparatus according to claim 10, further comprising:
a vibration section; and
a vibration control section that executes vibration control of the vibration section, wherein
the vibration control section vibrates the vibration section in different vibration modes depending on the plural detection positions.

15. A switch comprising:
an operation section that can move in a predetermined direction from an initial position by a user operation;
a position adjustment section that adjusts, in the predetermined direction, an amount of movement of the operation section from the initial position to a detection position; and
a position detection section that detects a position of the operation section with respect to the detection position.

16. The switch according to claim 15, wherein
the position adjustment section adjusts the detection position in the predetermined direction.

17. The switch according to claim 15, wherein
the position adjustment section adjusts the initial position of the operation section in the predetermined direction.

18. The switch according to claim 15, wherein
the position detection section includes a light emission section configured to emit output light at the detection position and a light reception section configured to receive the output light emitted by the light emission section, and
the position detection section detects the position of the operation section with respect to the detection position on a basis of whether or not the light reception section has received the output light from the light emission section.
